(19) United States
(12) Patent Application Publication
(10) Pub. No.: US 2024/0288773 A1
(43) Pub. Date: Aug. 29, 2024

(54) METHOD FOR MANUFACTURING SEMICONDUCTOR SUBSTRATE, AND COMPOSITION

(71) Applicant: JSR CORPORATION, Tokyo (JP)

(72) Inventors: Masato DOBASHI, Tokyo (JP); Hiroyuki KOMATSU, Tokyo (JP); Eiji YONEDA, Tokyo (JP); Satoshi DEI, Tokyo (JP); Kengo EHARA, Tokyo (JP); Sho YOSHINAKA, Tokyo (JP); Takashi KATAGIRI, Tokyo (JP)

(73) Assignee: JSR CORPORATION, Tokyo (JP)

(21) Appl. No.: 18/636,755

(22) Filed: Apr. 16, 2024

Related U.S. Application Data
(63) Continuation-in-part of application No. PCT/JP2022/037579, filed on Oct. 7, 2022.

(30) Foreign Application Priority Data
Oct. 19, 2021 (JP) 2021-171110

(51) Int. Cl. G03F 7/11; G03F 7/075; G03F 7/32; H01L 21/027

(52) U.S. Cl. CPC G03F 7/11; G03F 7/0752; G03F 7/322; H01L 21/0275

(57) ABSTRACT

A method includes: applying a composition for forming a resist underlayer film directly or indirectly to a substrate to form a resist underlayer film; applying a composition for forming a resist film to the resist underlayer film to form a resist film; exposing the resist film to radiation; and developing the exposed resist film. The composition for forming a resist underlayer film includes: a polymer including a partial structure represented by formula (i); and a solvent. In the formula (i), Y¹ is a sulfonyl group, a carbonyl group, or an alkanediyl group; Y² is a sulfonyl group, a carbonyl group, or a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms.

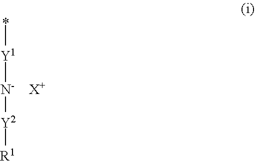

### CROSS-REFERENCE TO RELATED APPLICATIONS

The present application is a continuation-in-part application of International Patent Application No. PCT/JP2022/037579 filed Oct. 7, 2022, which claims priority to Japanese Patent Application No. 2021-171110 filed Oct. 19, 2021. The contents of these applications are incorporated herein by reference in their entirety.

### BACKGROUND OF THE DISCLOSURE

### Technical Field

The present disclosure relates to a method for manufacturing a semiconductor substrate and a composition.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate.

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). Various studies have been conducted on compositions for forming a resist underlayer film (see WO 2013/141015 A).

### SUMMARY

According to an aspect of the present disclosure, a method for manufacturing a semiconductor substrate, includes: applying a composition for forming a resist underlayer film directly or indirectly to a substrate to form a resist underlayer film; applying a composition for forming a resist film to the resist underlayer film to form a resist film; exposing the resist film to radiation; and developing the exposed resist film. The composition for forming a resist underlayer film includes: a polymer including a partial structure represented by formula (i); and a solvent.

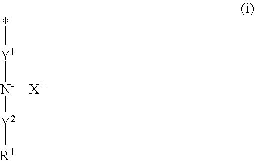

In the formula (i), Y¹ is a sulfonyl group, a carbonyl group, or an alkanediyl group; Y² is a sulfonyl group, a carbonyl group, or a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms; X⁺ is a monovalent onium cation; and * is a bond with another structure in the polymer.

According to another aspect of the present disclosure, a composition includes: a polymer including a partial structure represented by formula (i); and a solvent.

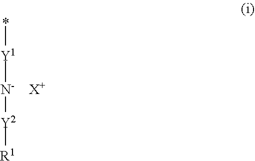

In the formula (i), Y¹ is a sulfonyl group, a carbonyl group, or an alkanediyl group; Y² is a sulfonyl group, a carbonyl group, or a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms; X⁺ is a monovalent onium cation; and * is a bond with another structure in the polymer.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In an embodiment of the present disclosure, a method for manufacturing a semiconductor substrate, includes: applying a composition for forming a resist underlayer film directly or indirectly to a substrate; applying a composition for forming a resist film to a resist underlayer film formed by applying the composition for forming a resist underlayer film; exposing the resist film formed by applying the composition for forming a resist film to radiation; and developing at least the exposed resist film. The composition for forming a resist underlayer film includes: a polymer including a partial structure represented by formula (i) (hereinafter, also referred to as “polymer [A]”); and a solvent (hereinafter, also referred to as “solvent [C]”).

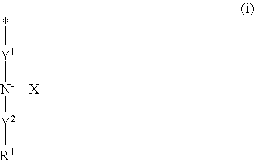

In the formula (i), Y¹ is a divalent group selected from the group consisting of a sulfonyl group, a carbonyl group, and an alkanediyl group; Y² is a divalent group selected from the group consisting of a sulfonyl group, a carbonyl group, and a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms; X⁺ is a monovalent onium cation; and * is a bond with another structure in the polymer.

In another embodiment of the present disclosure, a composition for forming a resist underlayer film, includes: a polymer comprising a partial structure represented by formula (i); and a solvent.

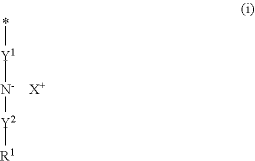

In the formula (i), Y¹ is a divalent group selected from the group consisting of a sulfonyl group, a carbonyl group, and an alkanediyl group; Y² is a divalent group selected from the group consisting of a sulfonyl group, a carbonyl group, and a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms; X⁺ is a monovalent onium cation; and * is a bond with another structure in the polymer.

According to the method for manufacturing a semiconductor substrate, semiconductor substrates can be efficiently manufactured because of the use of the composition for forming a resist underlayer film capable of forming a resist underlayer film having excellent solvent resistance and resist pattern rectangularity. According to the composition for forming a resist underlayer film, it is possible to form a film with excellent solvent resistance and resist pattern rectangularity. Therefore, it can be suitably used for manufacturing semiconductor devices and the like.

Hereinafter, a method for manufacturing a semiconductor substrate and a composition for forming a resist underlayer film according to each embodiment of the present disclosure will be described in detail. Combinations of suitable modes in the embodiments are also preferred.

<<Method for manufacturing semiconductor substrate>>

The method for manufacturing a semiconductor substrate includes applying a composition for forming a resist underlayer film directly or indirectly to a substrate (this step is hereinafter also referred to as “application step (I)”); applying a composition for forming a resist film to a resist underlayer film formed by applying the composition for forming a resist underlayer film (this step is hereinafter also referred to as “application step (II)”); exposing the resist film formed by applying the composition for forming a resist film to radiation (this step is hereinafter also referred to as “exposure step”); and developing at least the exposed resist film (this step is hereinafter also referred to as “development step”).

By the method for manufacturing a semiconductor substrate, a resist underlayer film superior in solvent resistance and resist pattern rectangularity can be formed due to the use of a prescribed composition for forming a resist underlayer film in the application step (I), so that a semiconductor substrate having a favorable pattern shape can be manufactured.

Preferably, the method for manufacturing a semiconductor substrate further includes, before the application step (II), heating at 200° C. or higher the resist underlayer film formed by applying the composition for forming a resist underlayer film (hereinafter also referred to as “heating step”).

The method for manufacturing a semiconductor substrate may further include, as necessary, directly or indirectly forming a silicon-containing film on the substrate (this step is hereinafter also referred to as “silicon-containing film formation step”) before the application step (I).

Hereinafter, the composition for forming a resist underlayer film to be used in the method for manufacturing a semiconductor substrate, and the respective steps in the case of including the heating step, which is a preferable step, and the silicon-containing film formation step, which is an optional step, will be described.

<Composition for forming resist underlayer film>

The composition for forming a resist underlayer film (this composition is hereinafter also referred to as “composition”) includes a polymer [A] and a solvent [C]. The composition may contain any optional component as long as the effect of the present invention is not impaired. The composition for forming a resist underlayer film can form a resist underlayer film superior in solvent resistance and resist pattern rectangularity owing to containing the polymer [A] and the solvent [C]. The reason for this is not clear, but can be expected as follows. Since the polymer having a sulfonimide salt structure, a sulfonamide salt structure, an imide salt structure, or the like as a partial structure (namely, the polymer [A]) is used as a main component of the composition for forming a resist underlayer film, solubility in an organic solvent can be reduced. In addition, an acid generated from the partial structure in the resist underlayer film supplies an acid to a bottom part of a resist film in the exposed portion in the exposure step, so that solubility in a developer at the bottom part of the resist film is enhanced and resist pattern rectangularity can be exhibited.

### <Polymer [A]>

The polymer [A] has a partial structure represented by the following formula (i). The composition may contain one kind or two or more kinds of the polymer [A].

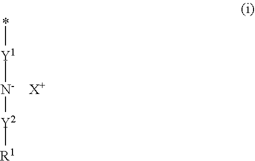

In the formula (i), Y¹ is a divalent group selected from the group consisting of a sulfonyl group, a carbonyl group, and an alkanediyl group; Y² is a divalent group selected from the group consisting of a sulfonyl group, a carbonyl group, and a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms; X⁺ is a monovalent onium cation; and * is a bond with another structure in the polymer.

Examples of the alkanediyl group represented by Y¹ include linear or branched alkanediyl groups having 1 to 10 carbon atoms such as a methanediyl group, an ethanediyl group, a propanediyl group, and a butanediyl group. Among them, a methanediyl group is preferable as the alkanediyl group represented by Y¹.

In the formula (1), examples of the monovalent organic group having 1 to 20 carbon atoms represented by R¹ include a monovalent hydrocarbon group having 1 to 20 carbon atoms, a group containing a divalent heteroatom-containing group between two carbon atoms of the foregoing hydrocarbon group, a group obtained by substituting some or all of the hydrogen atoms of the foregoing hydrocarbon group with a monovalent heteroatom-containing group, and a combination thereof. The “organic group” refers to a group having at least one carbon atom.

Examples of the monovalent hydrocarbon group having 1 to 20 carbon atoms include monovalent chain hydrocarbon groups having 1 to 20 carbon atoms, monovalent alicyclic hydrocarbon groups having 4 to 20 carbon atoms, monovalent aromatic hydrocarbon groups having 6 to 20 carbon atoms, and combinations thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent chain hydrocarbon group having 1 to 20 carbon atoms include alkyl groups such as a methyl group, an ethyl group, a n-propyl group, an i-propyl group, a n-butyl group, a sec-butyl group, and a tert-butyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 20 carbon atoms include cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, a pyrenyl group, and a benzyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, and groups obtained by combining them.

Examples of the monovalent heteroatom-containing group include a hydroxy group, a sulfanyl group, a cyano group, a nitro group, and halogen atoms.

R¹ may have a substituent other than the monovalent heteroatom-containing group. Examples of the substituent include monovalent chain hydrocarbon groups having 1 to 10 carbon atoms; halogen atoms such as a fluorine atom, a chlorine atom, a bromine atom, and an iodine atom; alkoxy groups such as a methoxy group, an ethoxy group, and a propoxy group; aryloxy groups such as a phenoxy group and a naphthyloxy group; alkoxycarbonyl groups such as a methoxycarbonyl group and an ethoxycarbonyl group; alkoxycarbonyloxy groups such as a methoxycarbonyloxy group and an ethoxycarbonyloxy group; acyl groups such as a formyl group, an acetyl group, a propionyl group, and a butyryl group; a cyano group, a nitro group, a hydroxy group, a carboxy group, and an oxo group (═O).

The R¹ is preferably a monovalent organic group having 1 to 20 carbon atoms in which a fluorine atom or a fluorinated hydrocarbon group is bonded to a carbon atom adjacent to Y² in the formula (i). As a result, the acid generated from the partial structure can be made strongly acidic, and the resist pattern rectangularity can be improved. Among them, R¹ is preferably a monovalent fluorinated alkyl group having 1 to 20 carbon atoms in which a fluorine atom or a fluorinated hydrocarbon group is bonded to a carbon atom adjacent to Y² in the formula (i). When Y² is a sulfonyl group or a carbonyl group, R¹ is more preferably a perfluoroalkyl group having 1 to 5 carbon atoms, and particularly preferably a trifluoromethyl group. When Y² is a single bond, R¹ is more preferably a fluoroalkyl group having 1 to 5 carbon atoms or a perfluoroalkyl group having 1 to 5 carbon atoms, and is particularly preferably a 2,2,2-trifluoroethyl group or a perfluoroethyl group.

Examples of the monovalent onium cation represented by X⁺ include a cation represented by the following formula (c-a) (hereinafter, also referred to as “cation (c-a)”), a cation represented by the following formula (c-b) (hereinafter, also referred to as “cation (c-b)”), and a cation represented by the following formula (c-c) (hereinafter, also referred to as “cation (c-c)”).

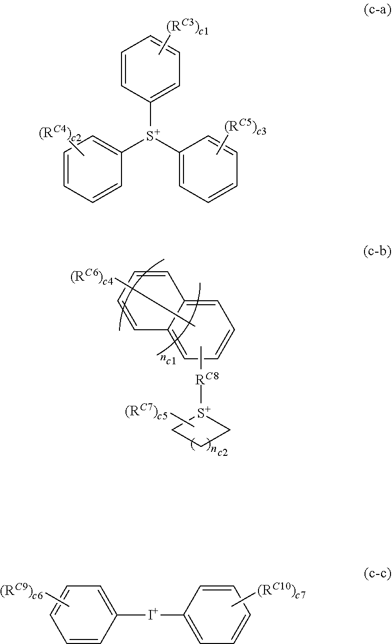

In the formula (c-a), R^{C3}, R^{C4} and R^{C5} each independently represent a substituted or unsubstituted linear or branched alkyl group having 1 to 12 carbon atoms, a substituted or unsubstituted aromatic hydrocarbon group having 6 to 12 carbon atoms, a halogen atom, —OSO₂—R^{CC1} or —SO₂—R^{CC2}, or a ring structure constituted by combining two or more of these groups with each other. R^{CC1} and R^{CC2} are each independently a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms. c1, c2, and c3 are each independently an integer of 0 to 5. When there are pluralities of R^{C3}s to R^{C5} s, R^{CC1}s and R^{CC2}s, the pluralities of R^{C3}s to R^{C5}s, R^{CC1}s and R^{CC2}s each may be identical or different.

In the above formula (c-b), R^{C6} is a substituted or unsubstituted linear or branched alkyl group having 1 to 8 carbon atoms, a substituted or unsubstituted aromatic hydrocarbon group having 6 to 8 carbon atoms, or a halogen atom. c4 is an integer of 0 to 7. When there are a plurality of R^{C6}s, the plurality of R^{C6}s may be identical or different, and the plurality of R^{C6} may represent a ring structure constituted by combining them with each other. R^{C7} is a substituted or unsubstituted linear or branched alkyl group having 1 to 7 carbon atoms, a substituted or unsubstituted aromatic hydrocarbon group having 6 or 7 carbon atoms, or a halogen atom. c5 is an integer of 0 to 6. When there are a plurality of R^{M}s, the plurality of R^{C7}s may be identical or different, and the plurality of R^{M}?s may represent a ring structure constituted by combining them with each other. n_{c2} is an integer of 0 to 3. R^{C3} is a single bond or a divalent organic group having 1 to 20 carbon atoms. nₑ₁ is an integer of 0 to 2.

In the formula (c-c), R^{C9} and R^{C10} each independently represent a substituted or unsubstituted linear or branched alkyl group having 1 to 12 carbon atoms, a substituted or unsubstituted aromatic hydrocarbon group having 6 to 12 carbon atoms, a halogen atom, a cyano group, a nitro group, —OSO₂—R^{CC3} or —SO₂—R^{CC4}, or a ring structure constituted by combining two or more of these groups with each other. R^{CC3} and R^{CC4} are each independently a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms. c6 and c7 are each independently an integer of 0 to 5. When there are pluralities of R^{C9}s, R^{C10}s, R^{CC3}s and R^{CC4}, the pluralities of R^{C9}s, R^{C10}s, R^{CC3}s and R^{CC4}s each may be identical or different.

Examples of the unsubstituted linear alkyl groups represented by R^{C3}, R^{C4}, R^{C5}, R^{C6}, R^{C7}, R^{C9}, and R^{C10} include a methyl group, an ethyl group, a n-propyl group, and a n-butyl group.

Examples of the unsubstituted branched alkyl groups represented by R^{C3}, R^{C4}, R^{C5}, R^{C6}, R^{C7}, R^{C9}, and R^{Cl0} include an isopropyl group, an isobutyl group, a sec-butyl group, and a t-butyl group.

Examples of the unsubstituted aromatic hydrocarbon groups represented by R^{C3}, R^{C4}, R^{C5}, R^{C9}, and R^{C10} include:

aryl groups such as a phenyl group, a tolyl group, a xylyl group, a mesityl group, and a naphthyl group; and

aralkyl groups such as a benzyl group and a phenethyl group.

Examples of the unsubstituted aromatic hydrocarbon groups represented by R^{C6} and R^{C7} include a phenyl group, a tolyl group, and a benzyl group.

Examples of the divalent organic group represented by R^{C8} include a group obtained by removing one hydrogen atom from the monovalent organic group represented by the R¹.

Examples of the substituent which may substitute a hydrogen atom that alkyl groups or aromatic hydrocarbon groups have represented by R^{C3}, R^{C4}, R^{C5}, R^{C6}, R^{C7}, R^{C9}, and R^{C10} include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group, a nitro group, and a hydroxy group. Among these, halogen atoms are preferred, and fluorine atoms are more preferred.

As R^{C3}, R^{C4}, R^{C5}, R^{C6}, R^{C7}, R^{C9}, and R^{C10}, unsubstituted linear or branched alkyl groups, halogen atoms, fluorinated alkyl groups, unsubstituted monovalent aromatic hydrocarbon groups, —OSO₂—R^{BB5}, and —SO₂—R^{BB5} are preferable, branched alkyl groups, halogen atoms, fluorinated alkyl groups and unsubstituted monovalent aromatic hydrocarbon groups are more preferable, and a t-butyl group and a fluorine atom are still more preferable. R^{BB5} is an unsubstituted monovalent alicyclic hydrocarbon group or an unsubstituted monovalent aromatic hydrocarbon group.

As c1, c2, and c3 in the formula (c-a), integers of 0 to 2 are preferable, 0 or 1 is more preferable, and 0 is still more preferable. As c4 in the formula (c-b), integers of 0 to 2 are preferable, 0 or 1 is more preferable, and 1 is still more preferable. As c5, integers of 0 to 2 are preferable, 0 or 1 is more preferable, and 0 is still more preferable. As n_{c2}, 2 or 3 is preferable, and 2 is more preferable. As n_{c1}, 0 or 1 is preferable, and 0 is more preferable. As c6 and c7 in the formula (c-c), integers of 0 to 2 are preferable, and 0 or 1 is more preferable.

Among them, the cation (c-a) and the cation (c-c) are preferable as X⁺. A triphenylsulfonium cation and a tris(4-fluorophenyl)sulfonium cation are more preferable as the cation (c-a). A diphenyliodonium cation, a bis(4-t-butylphenyl)iodonium cation, a bis(4-fluorophenyl) iodonium cation, a bis(4-bromophenyl) iodonium cation, a bis(4-cyanophenyl)iodonium cation, and a bis(4-nitrophenyl)iodonium cation are more preferable as the cation (c-c).

The polymer [A] preferably has a repeating unit represented by the following formula (1) (this unit is hereinafter also referred to as “repeating unit (1)”). When the polymer [A] has the repeating unit (1), the partial structure represented by the above formula (i) (namely, an acid generating structure such as a sulfonimide salt structure, a sulfonamide salt structure, or an imide salt structure) can be introduced into the polymer [A].

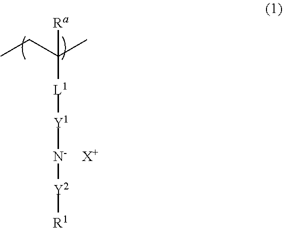

In the formula (1), R^{a} is a hydrogen atom or a substituted or unsubstituted monovalent hydrocarbon group having 1 to 20 carbon atoms. L¹ is a single bond or a divalent linking group other than an alkanediyl group. Y¹, Y², R¹, and X⁺ have the same definition as in the above formula (i).

In the formula (1), as the monovalent hydrocarbon group having 1 to 20 carbon atoms represented by R^{a}, the monovalent hydrocarbon groups having 1 to 20 carbon atoms in R¹ of the formula (i) can be suitably employed. When R^{a} has a substituent, as the substituent, a substituent which may be possessed by an alkyl group represented by R^{C3}, R^{C4}, R^{C5}, R^{C6}, R^{C7}, R^{C9} and R^{C10} of the above formulas (c-a) to (c-c) can be suitably employed. R^{a} is preferably a hydrogen atom.

Examples of the divalent linking group represented by L¹ include a divalent group other than alkanediyl groups that is a group obtained by removing one hydrogen atom from a monovalent organic group having 1 to 20 carbon atoms represented by R¹ of the formula (i). L¹ is preferably a divalent hydrocarbon group. Examples of the divalent hydrocarbon group as L¹ include a group obtained by removing one hydrogen atom from the monovalent hydrocarbon group having 1 to 20 carbon atoms as R¹ of the formula (i). Among them, L¹ is preferably a divalent aromatic hydrocarbon group having 6 to 20 carbon atoms, and more preferably a benzenediyl group.

Examples of the repeating unit (1) include repeating units represented by formulas (1-1) to (1-18).

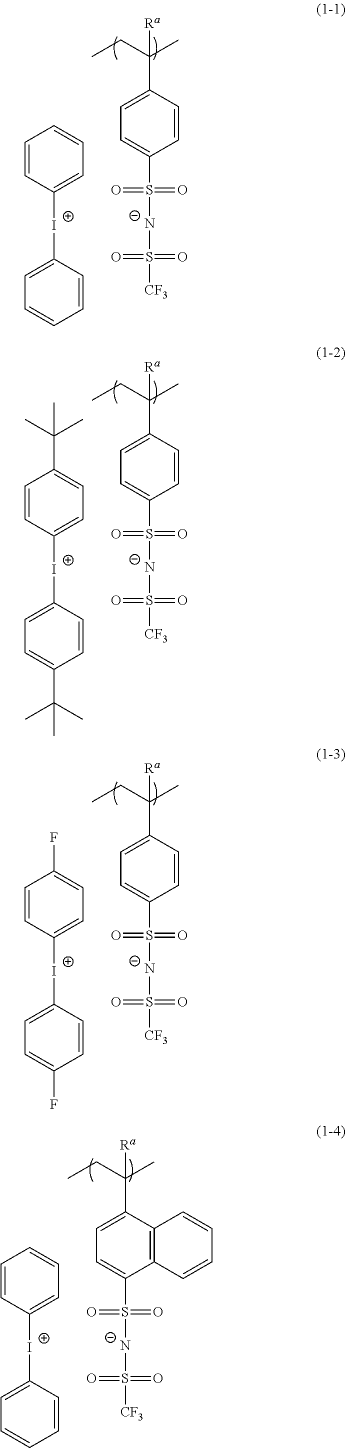

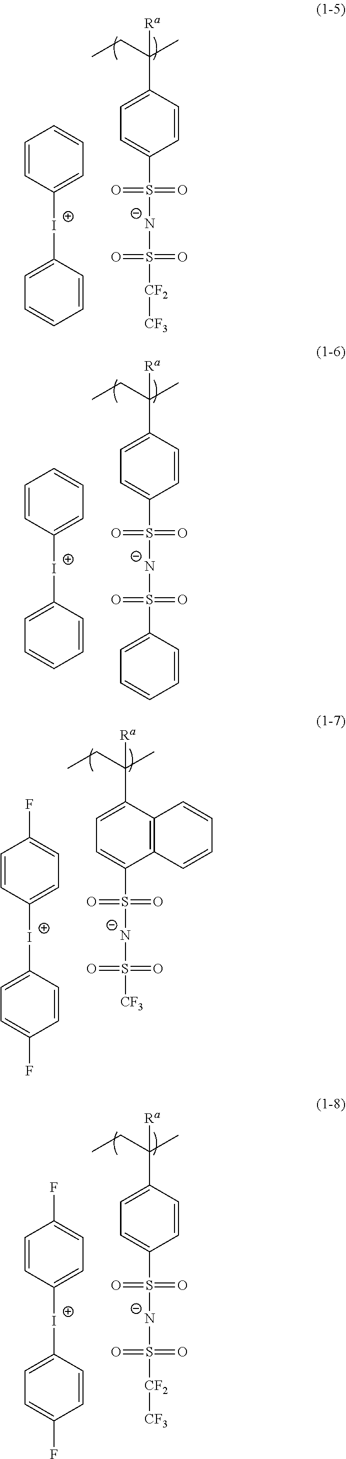

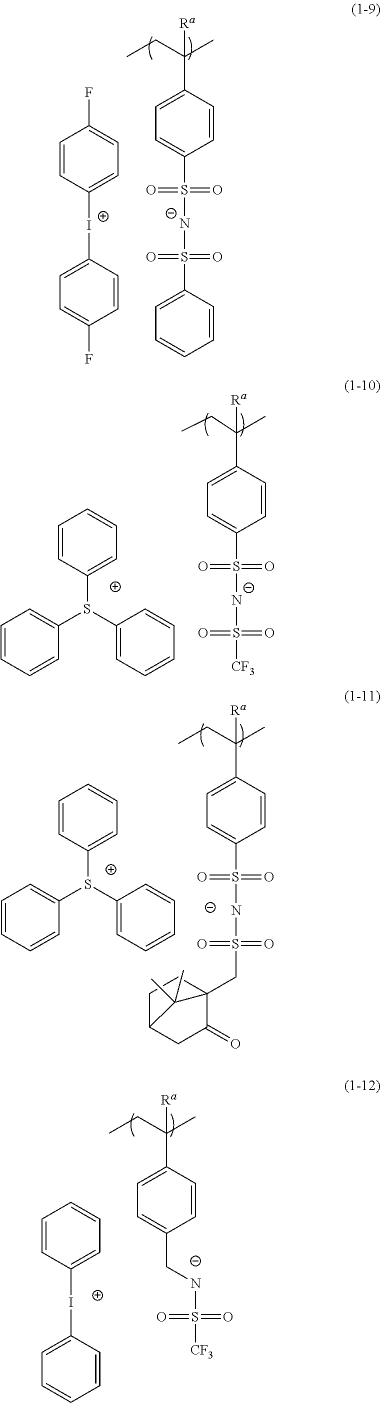

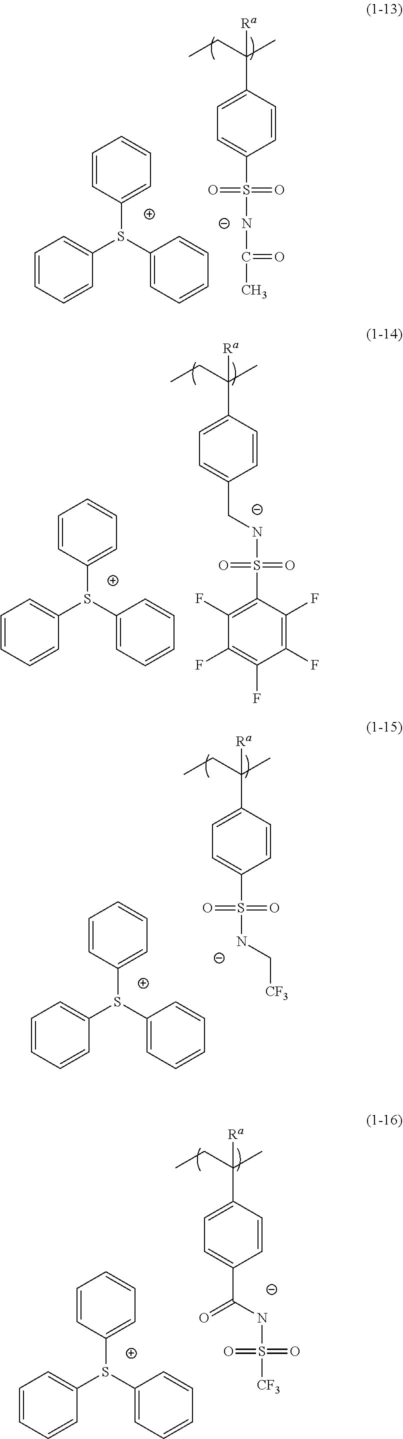

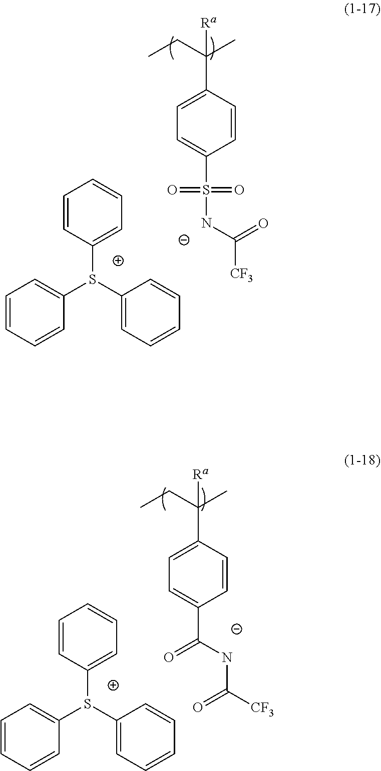

In the formulas (1-1) to (1-18), R^{a} has the same definition as that in the above formula (1). Among them, the repeating units represented by the formulas (1-1) to (1-3), (1-10) to (1-18) are preferable.

The lower limit of the content ratio of the repeating unit (1) (when multiple species are contained, the total content ratio is taken) accounting for among all the repeating units constituting the polymer [A] is preferably 1 mol %, more preferably 5 mol %, still more preferably 10 mol %, and particularly preferably 20 mol %. The upper limit of the content is preferably 100 mol %, more preferably 70 mol %, still more preferably 60 mol %, and particularly preferably 50 mol %. When the content ratio of the repeating unit (1) is set within the above range, solvent resistance and resist pattern rectangularity can be exhibited at a high level.

The polymer [A] preferably further has a repeating unit represented by the following formula (2) (excluding the case of corresponding to the repeating unit (1)) (this unit is hereinafter also referred to as “repeating unit (2)”). The polymer [A] may have one kind or two or more kinds of the repeating unit (2).

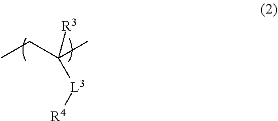

In the formula (2), R³ is a hydrogen atom or a substituted or unsubstituted monovalent hydrocarbon group having 1 to 20 carbon atoms. L³ is a single bond or a divalent linking group. R⁴ is a monovalent organic group having 1 to 20 carbon atoms.

As the monovalent hydrocarbon group having 1 to 20 carbon atoms represented by R³, the groups disclosed as the monovalent hydrocarbon group having 1 to 20 carbon atoms represented by R^{a} in the above formula (1) and the like can be suitably employed. When the R³ has a substituent, examples of the substituent include the groups disclosed as the substituent of R^{a} in the above formula (1).

Examples of the divalent linking group represented by L³ include groups disclosed as the divalent linking group represented by L¹ in the above formula (1), and L³ is preferably a single bond or —COO—.

Examples of the monovalent organic group having 1 to 20 carbon atoms represented by R⁴ include the monovalent organic groups having 1 to 20 carbon atoms represented by R¹ of the above formula (i). Among them, preferable examples of R⁴ include substituted or unsubstituted monovalent hydrocarbon groups represented by R^{a} in the above formula (1), substituted or unsubstituted monovalent heterocyclic groups, and groups containing —CO—, —CS—, —O—, —S—, —SO₂—, or —NR′—, or a combination of two or more thereof between carbon atoms or at a carbon chain terminal of those groups. R′ is a hydrogen atom or a monovalent hydrocarbon group having 1 to 10 carbon atoms. The R⁴ is preferably a substituted or unsubstituted monovalent aromatic hydrocarbon group, a substituted or unsubstituted monovalent chain hydrocarbon group, or a substituted or unsubstituted monovalent heterocyclic group.

Examples of the substituent that substitutes a part or all of the hydrogen atoms of the organic group include groups disclosed as the substituent of the monovalent hydrocarbon groups having 1 to 20 carbon atoms represented by R^{a} in the formula (1).

Examples of the heterocyclic group include a group obtained by removing one hydrogen atom from an aromatic heterocyclic structure and a group obtained by removing one hydrogen atom from an alicyclic heterocyclic structure. A 5-membered aromatic structure having aromaticity due to introducing a heteroatom is also included in the heterocyclic structure. Examples of the heteroatom include an oxygen atom, a nitrogen atom, and a sulfur atom.

Examples of the aromatic heterocyclic structure include:
oxygen atom-containing aromatic heterocyclic structures such as furan, pyran, benzofuran, and benzopyran;
nitrogen atom-containing aromatic heterocyclic structures such as pyrrole, imidazole, pyridine, pyrimidine, pyrazine, indole, quinoline, isoquinoline, acridine, phenazine, and carbazole;
sulfur atom-containing aromatic heterocyclic structures such as thiophene; and aromatic heterocyclic structures containing a plurality of heteroatoms such as thiazole, benzothiazole, thiazine, and oxazine.

Examples of the alicyclic heterocyclic structure include:
oxygen atom-containing alicyclic heterocyclic structures such as oxirane, oxetane, tetrahydrofuran, tetrahydropyran, dioxolane and dioxane;
nitrogen atom-containing alicyclic heterocyclic structures such as aziridine, pyrrolidine, pyrazolidine, piperidine and piperazine;
sulfur atom-containing alicyclic heterocyclic structures such as thietane, thiolane, and thiane;
alicyclic heterocyclic structures containing a plurality of heteroatoms such as oxazoline, morpholine, oxathiolane, oxazine, and thiomorpholine; and structures in which an alicyclic heterocyclic structure and an aromatic ring structure are combined such as benzoxazine.

Examples of the cyclic structure include a lactone structure, a cyclic carbonate structure, a sultone structure, and a structure containing a cyclic acetal.

Examples of the repeating unit represented by the formula (2) include repeating units represented by formulas (2-1) to (2-20).

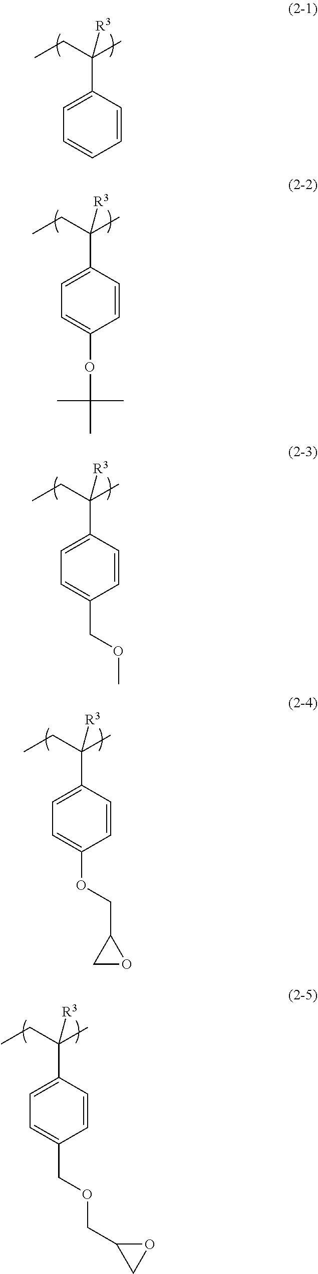

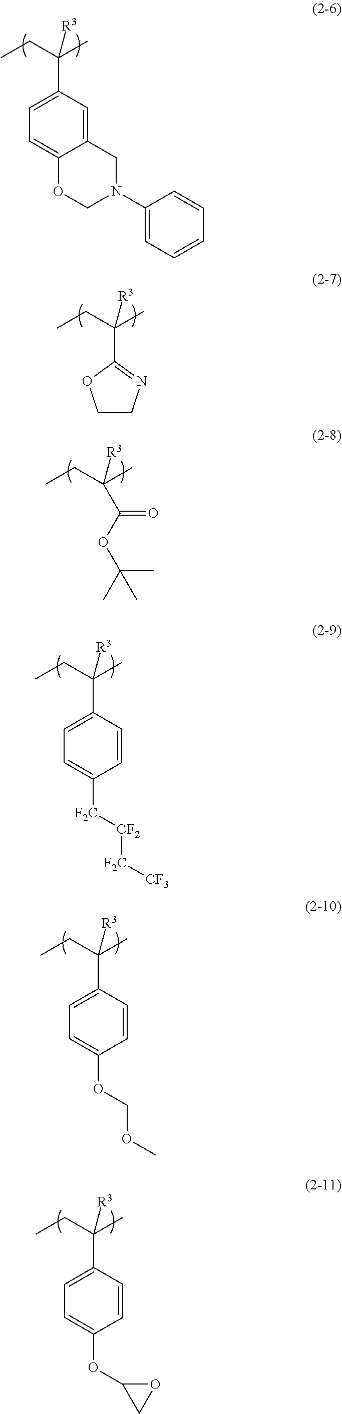

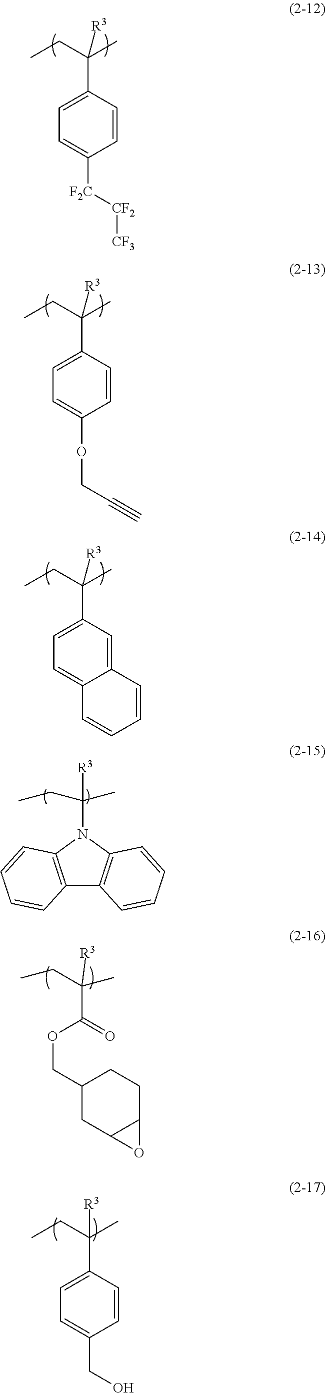

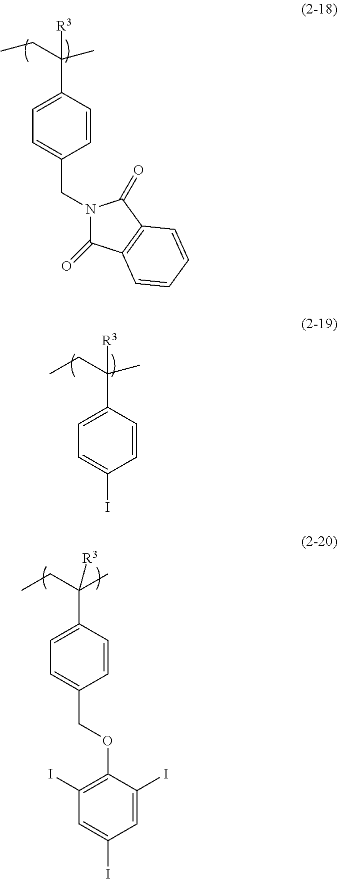

In the formulas (2-1) to (2-20), R³ has the same definition as that in the above formula (2). Among them, the repeating units represented by the formulas (2-1) to (2-8) are preferable.

When the polymer [A] has the repeating unit (2), the lower limit of the content ratio of the repeating unit (2) (when a plurality of types thereof are contained, the total content ratio is taken) accounting for among all the repeating units constituting the polymer [A] is preferably 5 mol %, more preferably 10 mol %, still more preferably 15 mol %, and particularly preferably 20 mol %. The upper limit of the content is preferably 95 mol %, more preferably 90 mol %, still more preferably 85 mol %, and particularly preferably 80 mol %. When the content ratio of the repeating unit (2) is set within the above range, solvent resistance and resist pattern rectangularity can be exhibited at a high level.

The polymer [A] may further have a repeating unit (W) represented by the following formula (W-1) or (W-2). The polymer [A] may have one kind or two or more kinds of the repeating unit (W).

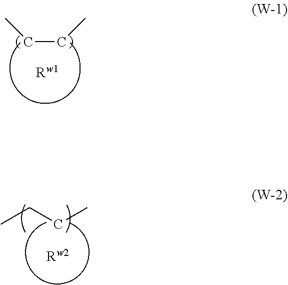

In the formula (W-1), R^{w1} represents a ring structure having 6 to 20 ring members formed together with the two carbon atoms in the formula. In the formula (W-2), R^{w2} represents a ring structure having 4 to 20 ring members formed together with the one carbon atom in the formula.

Examples of the ring structure having 6 to 20 ring members represented by R^{w1} include a structure corresponding to a monovalent alicyclic hydrocarbon group having 3 to 20 carbon atoms as R¹ of the above formula (1), a structure corresponding to a monovalent aromatic hydrocarbon group having 6 to 20 carbon atoms as R¹ of the above formula (1), a structure corresponding to a monovalent heterocyclic group as R⁴ of the above formula (2), a lactone structure, a cyclic carbonate structure, a sultone structure, a cyclic acetal, and combinations thereof. The ring structure may have a fused ring structure. The term “fused ring” refers to a ring structure in which adjacent rings share one side (two adjacent atoms).

Examples of the ring structure having 4 to 20 ring members represented by R^{w2} include groups obtained by expanding the ring structure having 6 to 20 ring members represented by R^{w1} to 4 to 20 ring members.

When R^{w1} and R^{w2} have a substituent, examples of the substituent include the groups disclosed as the substituent of R¹ in the above formula (i).

Examples of the repeating unit (W) include repeating units represented by the following formulas (W-1-1) to (W-1-2) and (W-2-1) to (W-2-2).

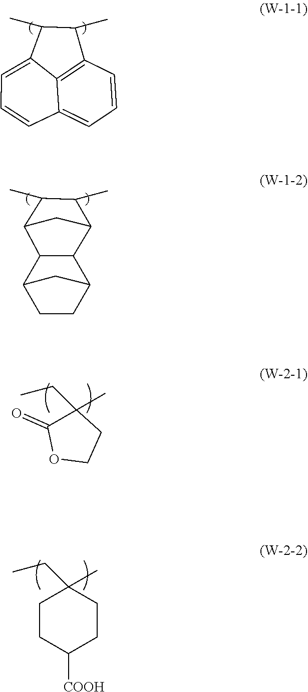

When the polymer [A] has the repeating unit (W), the lower limit of the content ratio of the repeating unit (W) (when a plurality of types thereof are contained, the total content ratio is taken) accounting for among all the repeating units constituting the polymer [A] is preferably 10 mol %, more preferably 20 mol %, and still more preferably 30 mol %. The upper limit of the content ratio is preferably 80 mol %, more preferably 70 mol %, and still more preferably 60 mol %.

The lower limit of the weight average molecular weight of the polymer [A] is preferably 1000, more preferably 2000, still more preferably 3000, and particularly preferably 5000. The upper limit of the molecular weight is preferably 22000, more preferably 20000, still more preferably 19000, and particularly preferably 18000. The weight average molecular weight is measured as described in EXAMPLES.

The lower limit of the content ratio of the polymer [A] accounting for among the components other than the solvent [C] in the composition for forming a resist underlayer film is preferably 10% by mass, more preferably 20% by mass, and still more preferably 30% by mass. The upper limit of the content ratio is preferably 100% by mass, more preferably 90% by mass, and still more preferably 80% by mass.

[Method for synthesizing polymer [A]]

The polymer [A] can be synthesized by performing radical polymerization, ion polymerization, polycondensation, polyaddition, addition condensation, or the like depending on the type of the monomer. For example, when the polymer [A] is synthesized by radical polymerization, the polymer can be synthesized by polymerizing monomers which will afford respective structural units using a radical polymerization initiator of the like in an appropriate solvent.

Examples of the radical polymerization initiator include azo radical initiators, such as azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), dimethyl 2,2′-azobisisobutyrate and dimethyl-2,2′-azobis(2-methylpropionate); and peroxide radical initiators, such as benzoyl peroxide, t-butyl hydroperoxide and cumene hydroperoxide. These radical initiators may be used singly, or two or more of them may be used in combination.

As the solvent to be used for the polymerization, the solvent [C] described later can be suitably employed. The solvents to be used for the polymerization may be used singly, or two or more solvents may be used in combination.

The reaction temperature in the polymerization is usually 40° C. to 150° C., and preferably 50° C. to 120° C. The reaction time is usually 1 hour to 48 hours, and preferably 1 hour to 24 hours.

[Other polymers]

The composition for forming a resist underlayer film may contain, in addition to the polymer [A], another polymer (hereinafter also referred to as “polymer [B]”). The composition may contain, for example, a polymer obtained via radical polymerization containing no repeating unit (1) (hereinafter also referred to as “polymer [B1]”) as the polymer [B]. Furthermore, the composition also may contain a polymer obtained via addition condensation (hereinafter also referred to as “polymer [B2]”). The composition may contain one kind or two or more kinds of the polymer [B1] and may contain one kind or two or more kinds of the polymer [B2].

### <Polymer [B1]>

The polymer [B1] may have the repeating unit described below together with the repeating unit (2) in the polymer [A] or in place of the repeating unit (2).

The polymer [B1] may have a repeating unit represented by formula (3) (this unit is hereinafter also referred to as “repeating unit (4)”):

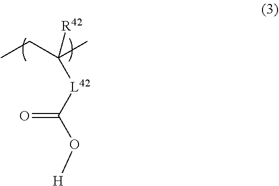

in the formula (3), R⁴² is a hydrogen atom or a substituted or unsubstituted monovalent hydrocarbon group having 1 to 20 carbon atoms; and L⁴² is a single bond or a divalent linking group.

In the formula (3), as the substituted or unsubstituted monovalent hydrocarbon group having 1 to 20 carbon atoms represented by R⁴², the groups disclosed as the substituted or unsubstituted monovalent hydrocarbon group having 1 to 20 carbon atoms represented by R^{a} in the formula (1) can be suitably employed.

In the formula (3), as the divalent linking group represented by L⁴², the groups disclosed as the divalent linking group represented by L¹ in the formula (1) can be suitably employed. As L⁴², a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, an arylene group obtained by removing one hydrogen atom from a monovalent aromatic hydrocarbon group having 6 to 20 carbon atoms, a carbonyl group, an oxygen atom, or a combination thereof is a preferable, and a single bond, an alkanediyl group having 1 to 5 carbon atoms, a cycloalkylene group having 5 to 7 carbon atoms, a phenylene group, a carbonyl group, an oxygen atom, or a combination thereof is more preferable.

Examples of the repeating unit represented by the formula (3) include repeating units represented by formulas (3-1) to (3-8).

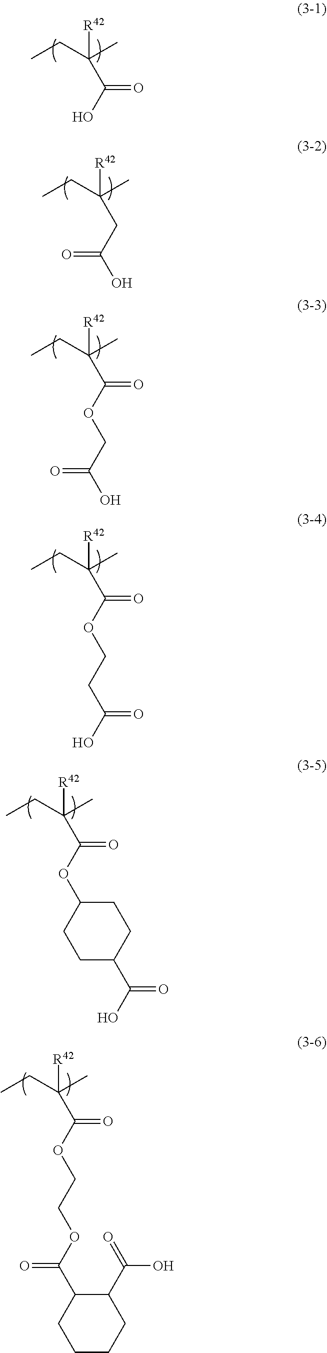

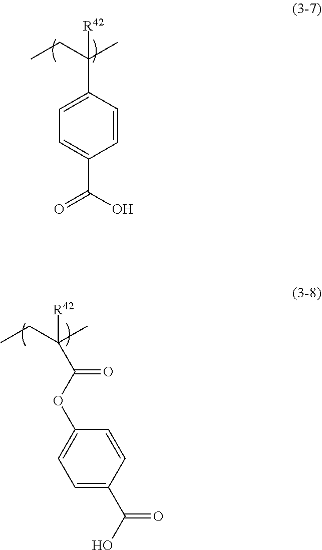

In the formulas (3-1) to (3-8), R² has the same definition as that in the above formula (3).

When the polymer [B1] has the repeating unit (3), the lower limit of the content ratio of the repeating unit (3) accounting for among all the repeating units constituting the polymer [B1] is preferably 30 mol %, more preferably 40 mol %, and still more preferably 50 mol %. The upper limit of the content is preferably 99 mol, more preferably 90 mol, and still more preferably 85 mol %.

The polymer [B1] may have a repeating unit represented by formula (4) (excluding the case of being the formula (3)) (this unit is hereinafter also referred to as “repeating unit (4)”):

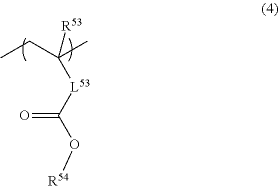

in the formula (4), R⁵³ is a hydrogen atom or a substituted or unsubstituted monovalent hydrocarbon group having 1 to 20 carbon atoms; L⁵³ is a single bond or a divalent linking group; and R⁵⁴ is a substituted or unsubstituted monovalent hydrocarbon group having 1 to 20 carbon atoms.

In the formula (4), as each of the substituted or unsubstituted monovalent hydrocarbon groups having 1 to 20 carbon atoms represented by R⁵³ and R⁵⁴, the groups disclosed as the substituted or unsubstituted monovalent hydrocarbon group having 1 to 20 carbon atoms represented by R^{a} in the formula (1) can be suitably employed. A hydrogen atom or a methyl group is preferable as R⁵³ from the viewpoint of the copolymerizability of a monomer that affords the repeating unit (4). A monovalent chain hydrocarbon group having 1 to 15 carbon atoms or an aromatic hydrocarbon group having 6 to 20 carbon atoms is preferable as R⁵⁴, and a monovalent branched alkyl group having 1 to 10 carbon atoms or an aromatic hydrocarbon group having 6 to 10 carbon atoms is more preferable. When R⁵³ or R⁵⁴ have a substituent, examples of the substituent preferably include the substituents that can be possessed by R^{a} of the above formula (1).

In the formula (4), as the divalent linking group represented by L⁵³, the groups disclosed as the divalent linking group represented by L¹ in the formula (1) can be suitably employed. As L⁵³, a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, a carbonyl group, an oxygen atom, or a combination thereof is a preferable, a single bond, an alkanediyl group having 1 to 5 carbon atoms, a cycloalkylene group having 5 to 7 carbon atoms, a carbonyl group, an oxygen atom, or a combination thereof is more preferable, and a single bond is still more preferable. When L⁵³ has a substituent, preferred examples of the substituent include the substituents that R^{a} in formula (1) above may have.

Examples of the repeating unit represented by the formula (4) include repeating units represented by formulas (4-1) to (4-17).

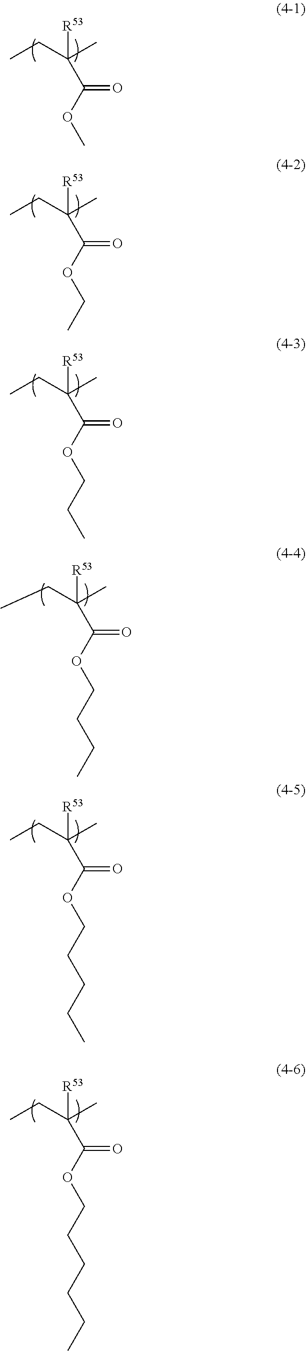

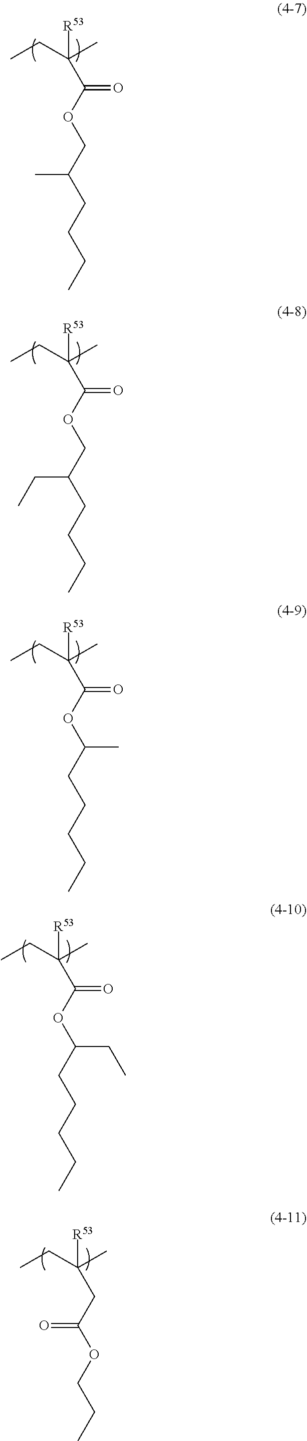

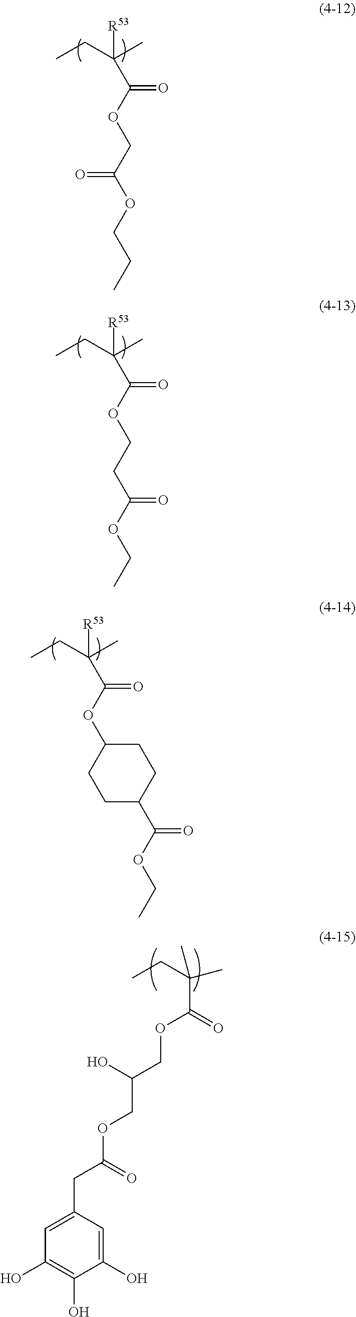

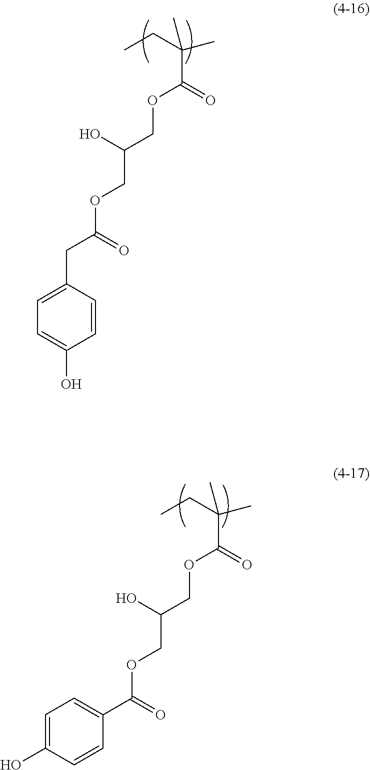

In the formulas (4-1) to (4-17), R⁵³ has the same definition as that in the above formula (4).

When the polymer [B1] has the repeating unit (4), the lower limit of the content ratio of the repeating unit (4) accounting for among all the repeating units constituting the polymer [B1] is preferably 1 mol %, more preferably 5 mol %, and still more preferably 10 mol %. The upper limit of the content is preferably 100 mol %, more preferably 50 mol %, and still more preferably 30 mol %.

The polymer [B1] may have a repeating unit represented by formula (5) (excluding the cases of being the formulas (3) and (4)) (this unit is hereinafter also referred to as “repeating unit (5)”):

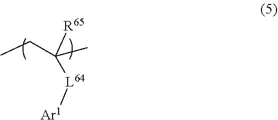

in the formula (5), R⁶⁵ is a hydrogen atom or a substituted or unsubstituted monovalent hydrocarbon group having 1 to 20 carbon atoms; L⁶⁴ is a single bond or a divalent linking group; and Ar¹ is a monovalent group having an aromatic ring having 6 to 20 ring members.

In the present specification, the term “ring members” refers to the number of atoms constituting the ring. For example, a biphenyl ring has 12 ring members, a naphthalene ring has 10 ring members, and a fluorene ring has 13 ring members.

In the formula (5), as the substituted or unsubstituted monovalent hydrocarbon group having 1 to 20 carbon atoms represented by R⁶⁵, the groups disclosed as the substituted or unsubstituted monovalent hydrocarbon group having 1 to 20 carbon atoms represented by R^{a} in the formula (1) can be suitably employed. A hydrogen atom or a methyl group is preferable as R⁶⁵ from the viewpoint of the copolymerizability of a monomer that affords the repeating unit (5). When R⁶⁵ has a substituent, examples of the substituent suitably include the substituents that can be possessed by R^{a} of the above formula (1).

In the formula (5), as the divalent linking group represented by L⁶⁴, the groups disclosed as the divalent linking group represented by L¹ in the formula (1) can be suitably employed. As L⁶⁴, a single bond, an alkanediyl group obtained by removing one hydrogen atom from an alkyl group having 1 to 10 carbon atoms, a cycloalkylene group obtained by removing one hydrogen atom from a cycloalkyl group having 5 to 10 carbon atoms, a carbonyl group, an oxygen atom, or a combination thereof is a preferable, a single bond, an alkanediyl group having 1 to 5 carbon atoms, a cycloalkylene group having 5 to 7 carbon atoms, a carbonyl group, an oxygen atom, or a combination thereof is more preferable, and a single bond is still more preferable.

In the above formula (5), examples of the aromatic ring having 6 to 20 ring numbers as Ar¹ include aromatic hydrocarbon rings such as a benzene ring, a naphthalene ring, an anthracene ring, an indene ring, and a pyrene ring, aromatic heterocyclic rings such as a pyridine ring, a pyrazine ring, a pyrimidine ring, a pyridazine ring, and a triazine ring, or a combination thereof. The aromatic ring of the Ar¹ is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring, and more preferably a benzene ring, a naphthalene ring, or a pyrene ring.

In the formula (5), suitable examples of the monovalent group having an aromatic ring having 6 to 20 ring members represented by Ar¹ include a group obtained by removing one hydrogen atom from the aromatic ring having 6 to 20 ring members in the Ar¹. When Ar¹ has a substituent, preferred examples of the substituent include the substituents that R^{a} in formula (1) above may have.

Examples of the repeating unit represented by the formula (5) include repeating units represented by formulas (5-1) to (5-10).

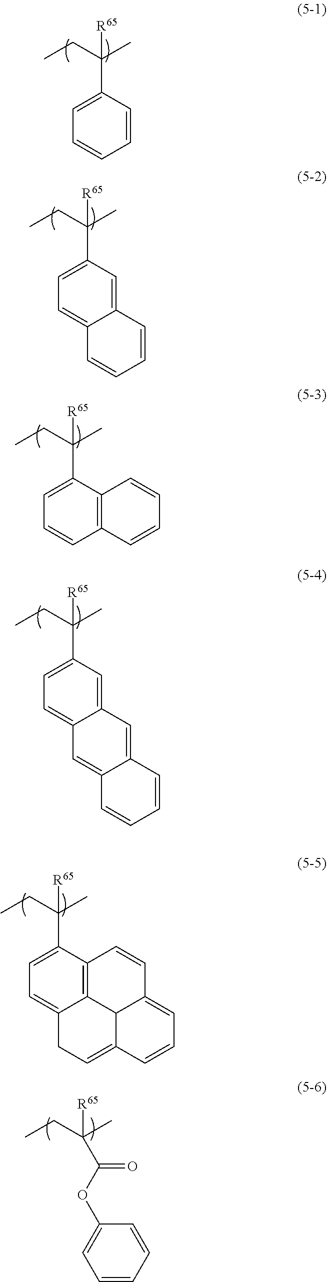

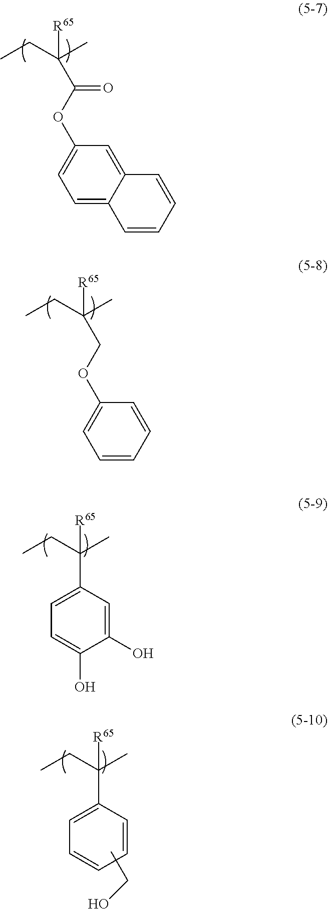

In the formulas (5-1) to (5-10), R⁶⁵ has the same definition as that in the above formula (5). Among them, the repeating unit represented by the formula (5-1) is preferable.

When the polymer [B1] has the repeating unit (5), the lower limit of the content ratio of the repeating unit (6) accounting for among all the repeating units constituting the polymer [B1] is preferably 5 mol %, more preferably 10 mol %, and still more preferably 20 mol %. The upper limit of the content is preferably 70 mol %, more preferably 60 mol %, and still more preferably 40 mol %.

The lower limit of the weight average molecular weight of the polymer [B1] is preferably 500, more preferably 1000, still more preferably 2000, and particularly preferably 3000. The upper limit of the molecular weight is preferably 10000, more preferably 9000, still more preferably 8000, and particularly preferably 7000.

When the composition for forming a resist underlayer film contains the polymer [B1], the lower limit of the content ratio of the polymer [B1] is preferably 10% by mass, more preferably 20% by mass, and still more preferably 30% by mass in the total mass of the polymer [A] and the polymer [B1]. The upper limit of the content ratio is preferably 80% by mass, more preferably 70% by mass, and still more preferably 60% by mass in the total mass of the polymer [A] and the polymer [B1].

### [Method for Synthesizing Polymer [B1]]

The polymer [B1] can be synthesized by radical polymerization. In this case, the polymer [B1] can be synthesized by polymerizing monomers which will afford respective structural units using a radical polymerization initiator of the like in an appropriate solvent.

### <Polymer [B2]>

The polymer [B2] has a repeating unit represented by the following formula (α). The polymer [B2] may have two or more kinds of the repeating unit represented by the following formula (α). The composition may contain one kind or two or more kinds of the polymer [B2].

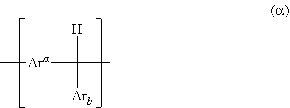

In the formula (α), Ar^{a} is a divalent group having an aromatic ring having 5 to 40 ring members. Ar^{b} is a hydrogen atom or a divalent group having an aromatic ring having 5 to 40 ring members.

In the formula (α), examples of the aromatic ring having 5 to 40 ring members in Ar^{a} and Ar^{b} include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, apyrazole ring, anoxazole ring, an isoxazole ring, a thiazole ring, a pyridine ring, a pyrazine ring, a pyrimidine ring, a pyridazine ring, and a triazine group, or combinations thereof. The aromatic ring of Ar^{a} and Ar^{b} is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring. The aromatic ring of Ar^{a} and Ar^{b} is more preferably a benzene ring, a naphthalene ring, or a pyrene ring.

In the formula (α), suitable examples of the divalent group having an aromatic ring having 5 to 40 ring members represented by Ar^{a} and Ar^{b} include a group obtained by removing two hydrogen atoms from the aromatic ring having 5 to 40 ring members as the Ar^{a}.

At least one of Ar^{a} and Ar^{b} preferably has at least one group selected from the group consisting of a group represented by the following formula (β-1) and a group represented by the following formula (β-2).

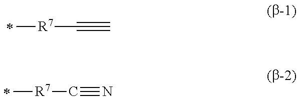

In the formulas (β-1) and (β-2), R⁷ is each independently a divalent organic group having 1 to 20 carbon atoms or a single bond. * is a bond with a carbon atom in the aromatic ring.

In the formulas (β-1) and (β-2), examples of the divalent organic group having 1 to 20 carbon atoms represented by R⁷ include a divalent hydrocarbon group having 1 to 20 carbon atoms, a group containing a divalent heteroatom-containing group between two carbon atoms of the foregoing hydrocarbon group, a group obtained by substituting some or all of the hydrogen atoms of the foregoing hydrocarbon group with a monovalent heteroatom-containing group, and a combination thereof.

Examples of the divalent hydrocarbon group having 1 to 20 carbon atoms include divalent chain hydrocarbon groups having 1 to 20 carbon atoms, divalent alicyclic hydrocarbon groups having 4 to 20 carbon atoms, divalent aromatic hydrocarbon groups having 6 to 20 carbon atoms, and combinations thereof.

Examples of the divalent chain hydrocarbon group having 1 to 20 carbon atoms include a methanediyl group, an ethanediyl group, a propanediyl group, a butanediyl group, a hexanediyl group, and an octanediyl group. In particular, an alkanediyl group having 1 to 8 carbon atoms is preferable.

Examples of the divalent alicyclic hydrocarbon group having 3 to 20 carbon atoms include cycloalkanediyl groups such as a cyclopentanediyl group and a cyclohexanediyl group; cycloalkenediyl groups such as a cyclopentenediyl group and a cyclohexenediyl group; bridged cyclic saturated hydrocarbon groups such as a norbornanediyl group, an adamantanediyl group, and a tricyclodecanediyl group; and bridged cyclic unsaturated hydrocarbon groups such as a norbornenediyl group and a tricyclodecenediyl group.

Examples of the divalent aromatic hydrocarbon group having 6 to 20 carbon atoms include a phenylene group, a naphthalenediyl group, an anthracenediyl group, a pyrenediyl group, a toluenediyl group, and a xylenediyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and an iodine atom.

Examples of the divalent heteroatom-containing group include —CO—, —CS—, —NH—, —O—, —S—, and groups obtained by combining them.

Examples of the monovalent heteroatom-containing group include a hydroxy group, a sulfanyl group, a cyano group, a nitro group, and halogen atoms.

A divalent hydrocarbon group having 1 to 10 carbon atoms such as a methanediyl group, an ethanediyl group, and a phenylene group, —O—, and a combination of them are preferable as R⁷, and amethanediyl group or a combination of a methanediyl group and —O— is more preferable.

It is preferable that the Ar^{a} has a group represented by the formula (β-1), and the group is represented by the following formula (β-1-1).

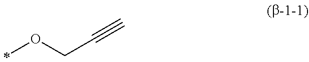

Ar^{a} and Ar^{b} may have a substituent other than the group represented by the formula (β-1) and the group represented by the formula (β-2). Examples of the substituent include monovalent chain hydrocarbon groups having 1 to 10 carbon atoms; halogen atoms such as a fluorine atom, a chlorine atom, a bromine atom, and an iodine atom; alkoxy groups such as a methoxy group, an ethoxy group, and a propoxy group; aryloxy groups such as a phenoxy group and a naphthyloxy group; alkoxycarbonyl groups such as a methoxycarbonyl group and an ethoxycarbonyl group; alkoxycarbonyloxy groups such as a methoxycarbonyloxy group and an ethoxycarbonyloxy group; acyl groups such as a formyl group, an acetyl group, a propionyl group, and a butyryl group; a cyano group, a nitro group, and a hydroxy group.

Examples of the repeating unit represented by the formula (α) include repeating units represented by the following formulas (α-1) to (α-7).

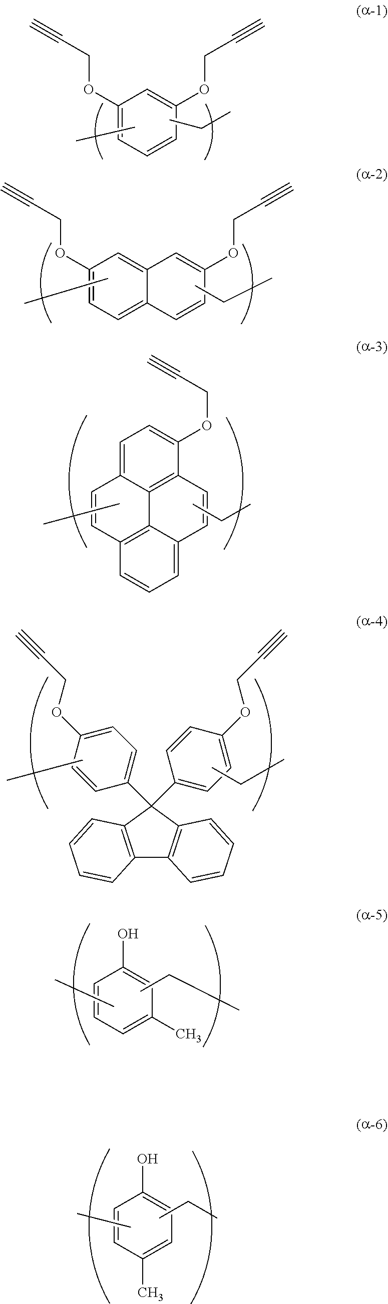

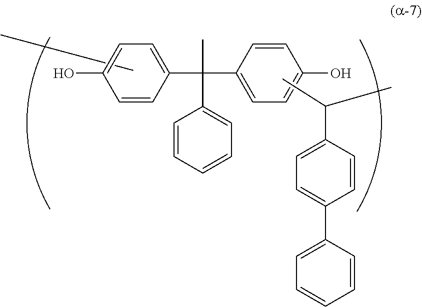

### (Other Polymers [B2])

As the polymer [B2], a resol-based polymer, a polyarylene-based polymer, a triazine-based polymer, a calixarene-based polymer, or the like can be used in addition to the polymer having a repeating unit represented by the above formula (α). These polymers can be produced by a known method.

### (Resol-Based Polymer)

The resol-based polymer is a polymer obtained by reacting a phenolic compound with an aldehyde using an alkaline catalyst.

Examples of the phenolic compound include:
phenols such as phenol, cresol, xylenol, resorcinol, and bisphenol A;
naphthols such as 1-naphthol, 2-naphthol, 1,5-dihydroxynaphthalene, 2,7-dihydroxynaphthalene, and 9,9-bis(6-hydroxynaphthyl)fluorene;
anthrols such as 9-anthrol; and hydroxypyrenes such as 1-hydroxypyrene and 2-hydroxypyrene.

Examples of the aldehyde include:
aldehydes such as formaldehyde, acetaldehyde, benzaldehyde, 1-pyrenecarboxaldehyde; and
aldehyde sources such as paraformaldehyde, trioxane, and paraldehyde.

### (Polyarylene-Based Polymer)

The polyarylene-based polymer is a polymer having a structural unit derived from a compound containing an arylene skeleton. Examples of the arylene skeleton include a phenylene skeleton, a naphthylene skeleton, and a biphenylene skeleton.

Examples of the polyarylene-based polymer include a polyarylene ether, a polyarylene sulfide, a polyarylene ether sulfone, a polyarylene ether ketone, and a polymer having a structural unit containing a biphenylene skeleton and a structural unit derived from a compound containing an acenaphthylene skeleton.

### (Triazine-Based Polymer)

The triazine-based polymer is a polymer having a structural unit derived from a compound having a triazine skeleton. Examples of the compound having a triazine skeleton include a melamine compound and a cyanuric acid compound.

### (Calixarene-Based Polymer)

A calixarene-based polymer is a cyclic oligomer in which a plurality of aromatic rings to which a hydroxyl group is bonded are bonded via hydrocarbon groups in a cyclic form or a compound in which some or all of the hydrogen atoms in the hydroxy groups, aromatic rings, or hydrocarbon groups of the cyclic oligomer are substituted.

The lower limit of the weight average molecular weight of the polymer [B2] is preferably 500, more preferably 1000, still more preferably 1500, and particularly preferably 2000. The upper limit of the molecular weight is preferably 8000, more preferably 7000, still more preferably 6000, and particularly preferably 5000.

When the composition for forming a resist underlayer film contains the polymer [B2], the lower limit of the content ratio of the polymer [B2] is preferably 10% by mass, more preferably 20% by mass, and still more preferably 30% by mass in the total mass of the polymer [A] and the polymer [B2]. The upper limit of the content ratio is preferably 80% by mass, more preferably 70% by mass, and still more preferably 60% by mass in the total mass of the polymer [A] and the polymer [B2].

### [Method for Synthesizing Polymer [B2]]

Typically, the polymer [B2] can be synthesized via acid addition condensation between an aromatic ring compound as a precursor having a phenolic hydroxy group to afford Ar^{a} of the above formula (α) and an aldehyde derivative as a precursor, and a subsequent nucleophilic substitution reaction by a phenolic hydroxy group to a halogenated hydrocarbon corresponding to the group represented by the above formula (β-1) or (β-2).

### <Solvent [C]>

The solvent [C] is not particularly limited as long as it can dissolve or disperse the compound [A], the acid generating agent [B], and optional components contained as necessary.

Examples of the solvent [C] include a hydrocarbon-based solvent, an ester-based solvent, an alcohol-based solvent, a ketone-based solvent, an ether-based solvent, and a nitrogen-containing solvent. The solvent [C] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, n-propanol, 4-methyl-2-pentanol and 2,2-dimethyl-1-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, 2-heptanone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether, propylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [C], alcohol-based solvents, ether-based solvents, and ester-based solvents are preferable, monoalcohol-based solvents, polyhydric alcohol partial ether-based solvents, polyhydric alcohol partial ether carboxylate-based solvents, and lactic acid ester-based solvents are more preferable, and 4-methyl-2-pentanol, 2,2-dimethyl-1-propanol, propylene glycol monomethyl ether, propylene glycol monomethyl ether acetate, and ethyl lactate are still more preferable.

The lower limit of the content ratio of the solvent [C] in the composition for forming a resist underlayer film is preferably 50% by mass, more preferably 60% by mass, and still more preferably 70% by mass. The upper limit of the content ratio is preferably 99.9% by mass, more preferably 99% by mass, and still more preferably 95% by mass.

### (Optional Component)

The composition for forming a resist underlayer film may include an optional component as long as the effect of the composition is not impaired. Examples of the optional component include a crosslinking agent, an acid generating agent, a dehydrating agent, an acid diffusion controlling agent, and a surfactant. The optional component may be used singly or two or more kinds thereof may be used in combination.

(Crosslinking agent [D]) The type of the crosslinking agent [D] is not particularly limited, and a publicly known crosslinking agent can be freely selected and used. Preferably, at least one selected from polyfunctional (meth)acrylates, cyclicether-containing compounds, glycolurils, diisocyanates, melamines, benzoguanamines, polynuclear phenols, polyfunctional thiol compounds, polysulfide compounds, and sulfide compounds is preferably used as the crosslinking agent. When the composition contains the crosslinking agent [D], crosslinking of the polymer [A] and, as necessary, the polymer [B] can be advanced, and the solvent resistance of the resist underlayer film can be improved.

The polyfunctional (meth)acrylate is not particularly limited as long as it is a compound having two or more (meth)acryloyl groups, and examples thereof include a polyfunctional (meth)acrylate obtained by reacting an aliphatic polyhydroxy compound with (meth)acrylic acid, a caprolactone-modified polyfunctional (meth)acrylate, an alkylene oxide-modified polyfunctional (meth)acrylate, a polyfunctional urethane (meth)acrylate obtained by reacting a (meth)acrylate having a hydroxy group with a polyfunctional isocyanate, and a polyfunctional (meth)acrylate having a carboxyl group obtained by reacting a (meth)acrylate having a hydroxy group with an acid anhydride.

Specifically, examples of the polyfunctional (meth)acrylate include trimethylolpropane tri(meth)acrylate, ditrimethylolpropane tetra(meth)acrylate, pentaerythritol tri(meth)acrylate, pentaerythritol tetra(meth)acrylate, dipentaerythritol penta(meth)acrylate, dipentaerythritol hexa(meth)acrylate, glycerin tri(meth)acrylate, tris(2-hydroxyethyl)isocyanurate tri(meth)acrylate, ethylene glycol di(meth)acrylate, 1,3-butanediol di(meth)acrylate, 1,4-butanediol di(meth)acrylate, 1,6-hexanediol di(meth)acrylate, neopentyl glycol di(meth)acrylate, diethylene glycol di(meth)acrylate, triethylene glycol di(meth)acrylate, dipropylene glycol di(meth)acrylate, and bis(2-hydroxyethyl)isocyanurate di(meth)acrylate.

Examples of the cyclic ether-containing compound include oxiranyl group-containing compounds such as 1,6-hexanediol diglycidyl ether, 3′,4′-epoxycyclohexenylmethyl-3′,4′-epoxycyclohexenecarboxylat e, vinylcyclohexene monooxide 1,2-epoxy-4-vinylcyclohexene, and 1,2:8,9 diepoxylimonene; and oxetanyl group-containing compounds such as 3-ethyl-3-hydroxymethyloxetane, 2-ethylhexyloxetane, xylylene bisoxetane, and 3-ethyl-3{[(3-ethyloxetan-3-yl)methoxy]methyl}oxetane. These cyclic ether-containing compounds can be used singly, or two or more types thereof may be used in combination.

Examples of the glycolurils include compounds derived from tetramethylolglycoluril, tetramethoxyglycoluril, tetramethoxymethylglycoluril, and tetramethylolglycoluril through methoxymethylation of 1 to 4 methylol groups thereof, or mixtures of the compounds, compounds derived from tetramethylolglycoluril through acyloxymethylation of 1 to 4 methylol groups thereof, and glycidylglycolurils.

Examples of the glycidylglycolurils include 1-glycidylglycoluril, 1,3-diglycidylglycoluril, 1,4-diglycidylglycoluril, 1,6-diglycidylglycoluril, 1,3,4-triglycidylglycoluril, 1,3,4,6-tetraglycidylglycoluril, 1-glycidyl-3a-methylglycoluril, 1-glycidyl-6a-methylglycoluril, 1,3-diglycidyl-3a-methylglycoluril, 1,4-diglycidyl-3a-methylglycoluril, 1,6-diglycidyl-3a-methylglycoluril, 1,3,4-triglycidyl-3a-methylglycoluril, 1,3,4-triglycidyl-6a-methyglycoluril, 1,3,4,6-tetraglycidyl-3a-methylglycoluril, 1-glycidyl-3a,6a-dimethylglycoluril, 1,3-diglycidyl-3a,6a-dimethylglycoluril, 1,4-diglycidyl-3a,6a-dimethylglycoluril, 1,6-diglycidyl-3a,6a-dimethylglycoluril, 1,3,4-triglycidyl-3a,6a-dimethylglycoluril, 1,3,4,6-tetraglycidyl-3a,6a-dimethylglycoluril, 1-glycidyl-3a,6a-diphenylglycoluril, 1,3-diglycidyl-3a,6a-diphenylglycoluril, 1,4-diglycidyl-3a,6a-diphenylglycoluril, 1,6-diglycidyl-3a,6a-diphenylglycoluril, 1,3,4-triglycidyl-3a,6a-diphenylglycoluril, and 1,3,4,6-tetraglycidyl-3a,6a-diphenylglycoluril. These glycolurils can be used singly, or two or more types thereof may be used in combination.

Examples of the diisocyanates include 2,3-tolylenediisocyanate, 2,4-tolylenediisocyanate, 3,4-tolylenediisocyanate, 3,5-tolylenediisocyanate, 4,4′-diphenylmethanediisocyanate, hexamethylenediisocyanate, and 1,4-cyclohexanediisocyanate.

Examples of the melamines include melamine, monomethylolmelamine, dimethylolmelamine, trimethylolmelamine, tetramethylolmelamine, pentamethylolmelamine, hexamethylolmelamine, monobutylolmelamine, dibutylolmelamine, tributylolmelamine, tetrabutylolmelamine, pentabutylolmelamine, and hexabthyolmelamine, and alkylated derivatives of these methylolmelamines or butylolmelamines. These melamines can be used singly, or two or more types thereof may be used in combination.

Examples of the benzoguanamines include benzoguanamine in which amino groups are modified with four alkoxymethyl groups (alkoxymethylol groups) (tetraalkoxymethylbenzoguanamines (tetraalkoxymethylolbenzoguanamines)), such as tetramethoxymethylbenzoguanamine;
benzoguanamine in which amino groups are modified with four groups in total of alkoxymethyl groups (especially, methoxymethyl groups) and hydroxymethyl groups (methylol groups);
benzoguanamine having amino groups modified with three or less alkoxymethyl groups (especially, methoxymethyl groups); and benzoguanamine in which amino groups are modified with three or less groups in total of alkoxymethyl groups (especially, methoxymethyl groups) and hydroxymethyl groups.

These benzoguanamines can be used singly, or two or more types thereof may be used in combination.

Examples of the polynuclear phenols include binuclear phenols such as 4,4′-biphenyldiol, 4,4′-methylenebisphenol, 4,4′-ethylidenebisphenol, and bisphenolA; trinuclear phenols such as 4,4′,4‘ ’-methylidenetrisphenol, 4,4′-(1-(4-(1-(4-hydroxyphenyl)-1-methylethyl)phenyl)ethyliden e)bisphenol, and 4,4′-(1-(4-(1-(4-hydroxy-3,5-bis(methoxymethyl)phenyl)-1-methy lethyl)phenyl)ethylidene)bis(2,6-bis(methoxymethyl)phenol); and polyphenols such as novolac. These polynuclear phenols can be used singly, or two or more types thereof may be used in combination.

The polyfunctional thiol compound is a compound having two or more mercapto groups in one molecule, and specifically, examples thereof include compounds having two mercapto groups such as 1,2-ethanedithiol, 1,3-propanedithiol, 1,4-butanedithiol, 2,3-butanedithiol, 1,5-pentanedithiol, 1,6-hexanedithiol, 1,8-octanedithiol, 1,9-nonanedithiol, 2,3-dimercapto-1-propanol, dithioerythritol, 2,3-dimercaptosuccinic acid, 1,2-benzenedithiol, 1,2-benzenedimethanethiol, 1,3-benzenedithiol, 1,3-benzenedimethanethiol, 1,4-benzenedimethanethiol, 3,4-dimercaptooluene, 4-chloro-1,3-benzenedithiol, 2,4,6-trimethyl-1,3-benzenedimethanethiol, 4,4′-thiodiphenol, 2-hexylamino-4,6-dimercapto-1,3,5-triazine, 2-diethylamino-4,6-dimercapto-1,3,5-triazine, 2-cyclohexylamino-4,6-dimercapto-1,3,5-triazine, 2-di-n-butylamino-4,6-dimercapto-1,3,5-triazine, ethylene glycol bis(3-mercaptopropionate), butanediol bisthioglycolate, ethylene glycol bisthioglycolate, 2,5-dimercapto-1,3,4-thiadiazole, 2,2′-(ethylenedithio)diethanethiol, and 2,2-bis(2-hydroxy-3-mercaptopropoxyphenylpropane); compounds having three mercapto groups such as 1,2,6-hexanetrioltrithioglycolate, 1,3,5-trithiocyanuric acid, trimethylolpropane tris(3-mercaptopropionate), and trimethylolpropane tristhioglycolate; and compounds having 4 or more mercapto groups such as pentaerythritol tetrakis(2-mercaptoacetate), pentaerythritol tetrakis(2-mercaptopropionate) pentaerythritol tetrakis(3-mercaptopropionate), pentaerythritol tetrakis(3-mercaptobutyrate), and 1,3,5-tris(3-mercaptobutyryloxyethyl)-1,3,5-triazine-2,4,6(1H,3H,5H)-trione. These polyfunctional thiol compounds can be used singly, or two or more types thereof may be used in combination.

When the composition for forming a resist underlayer film contains the crosslinking agent [D], the lower limit of the content of the crosslinking agent [D] is preferably 10 parts by mass, more preferably 20 parts by mass, and still more preferably 30 parts by mass per 100 parts by mass of the polymer [A] or per 100 parts by mass in total of the polymers [A] and [B]. The upper limit of the content is preferably 100 parts by mass, more preferably 90 parts by mass, and still more preferably 80 parts by mass.

### [Method for Preparing Composition for Forming Resist Underlayer Film]

The composition for forming a resist underlayer film can be prepared by mixing the polymer [A], the solvent [C] and, as necessary, an optional component in a prescribed ratio and preferably filtering the resulting mixture through a membrane filter having a pore size of 0.5 μm or less, or the like.

### [Silicon-Containing Film Forming Step]

In this step performed before the application step (I), a silicon-containing film is formed directly or indirectly on a substrate.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the substrate is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., and still more preferably 200° C. The upper limit of the temperature is preferably 550° C., more preferably 450° C., and still more preferably 300° C.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film can be measured in the same manner as for the average thickness of the resist underlayer film.

Examples of a case where the silicon-containing film is formed indirectly on the substrate include a case where the silicon-containing film is formed on a low dielectric insulating film or an organic underlayer film formed on the substrate.

### [Application Step (I)]

In this step, a composition for forming a resist underlayer film is applied to the silicon-containing film formed on the substrate. The method of the application of the composition for forming a resist underlayer film is not particularly limited, and the application can be performed by an appropriate method such as spin coating, cast coating, or roll coating. As a result, a coating film is formed, and volatilization of the solvent [C] or the like occurs, so that a resist underlayer film is formed.

The lower limit of the average thickness of the resist underlayer film to be formed is preferably 0.5 nm, more preferably 1 nm, and still more preferably 2 nm. The upper limit of the average thickness is preferably 50 nm, more preferably 20 nm, still more preferably 10 nm, and particularly preferably 7 nm. The average thickness is measured as described in Examples.

When the composition for forming a resist underlayer film is applied directly to the substrate, the silicon-containing film formation step may be omitted.

### [Heating Step]

Next, the resist underlayer film formed by the application step (I) is heated at a temperature of 200° C. or more. Decomposition of the sulfonimide salt structure in the polymer [A] is promoted by the heating of the resist underlayer film. This step is performed before the application step (II).

The heating of the coating film may be performed either in the air atmosphere or in a nitrogen atmosphere. The lower limit of the heating temperature is just required to be 200° C., but is preferably 210° C., more preferably 220° C., and still more preferably 230° C. The upper limit of the heating temperature is preferably 400° C., more preferably 350° C., and still more preferably 280° C. The lower limit of the heating time is preferably 30 seconds, more preferably 40 seconds, and still more preferably 60 seconds. The upper limit of the time is preferably 800 seconds, more preferably 400 seconds, and still more preferably 200 seconds.

### [Application Step (II)]

In this step, a composition for forming a resist film is formed on the resist underlayer film formed by the step of applying a composition for forming a resist underlayer film. The method of applying the composition for forming a resist film is not particularly limited, and examples thereof include a spin coating method.

Describing this step more in detail, for example, a resist composition is applied such that a resist film formed comes to have a prescribed thickness, and then prebaking (hereinafter also referred to as “PB”) is performed to volatilize the solvent in the coating film. As a result, a resist film is formed.

The PB temperature and the PB time may be appropriately determined according to the type and the like of the composition for forming a resist film to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

Examples of the composition for forming a resist film to be used in this step include a positive or negative chemically amplified resist composition containing a radiation-sensitive acid generating agent, a positive resist composition containing an alkali-soluble resin and a quinonediazide-based photosensitizer, a negative resist composition containing an alkali-soluble resin and a crosslinking agent, and a metal-containing resist composition containing a metal such as tin or zirconium. As the composition for forming a resist film used in this step, a so-called positive-type composition for forming a resist film for alkali development is preferably used. Such a composition for forming a resist film is preferably a positive-type composition for forming a resist film containing, for example, a resin having an acid-dissociable group and a radiation-sensitive acid generator and intended for exposure to ArF excimer laser light (for ArF exposure) or exposure to extreme ultraviolet rays (for EUV exposure).

### [Exposure Step]

In this step, a resist film formed in the step of applying a composition for forming a resist film is exposed to radiation. This step causes a difference in solubility in a basic solution as a developer between an exposed portion and an unexposed portion in the resist film. More specifically, the solubility of the exposed portion in the basic solution in the resist film is increased.

Radiation to be used for the exposure can be appropriately selected according to the type or the like of the composition for forming a resist film to be used. Examples thereof include electromagnetic rays such as visible rays, ultraviolet rays, far-ultraviolet, X-rays, and γ-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred. Further, the exposure conditions can be determined as appropriate depending on the type of resist film forming composition used.

In this step, post exposure baking (hereinafter, also referred to as “PEB”) can be performed after the exposure in order to improve the resist film performance such as resolution, pattern profile, and developability. The PEB temperature and the PEB time may be appropriately determined according to the type and the like of the composition for forming a resist film to be used. The lower limit of the PEB temperature is preferably 50° C., and more preferably 70° C. The upper limit of the PEB temperature is preferably 200° C., and more preferably 150° C. The lower limit of the PEB time is preferably 10 seconds, and more preferably 30 seconds. The upper limit of the PEB time is preferably 600 seconds, and more preferably 300 seconds.

### [Development Step]

In this step, at least the exposed resist film is developed. This step is preferably alkali development in which the developer to be used is a basic solution. Since there is a difference in solubility in a basic solution as a developer between the exposed portion and the unexposed portion in the resist film as a result of the exposure step, the exposed portion having a relatively high solubility in the basic solution is removed via alkali development and a resist pattern is formed.

In the step of developing the exposed resist film, it is preferable to further develop a part of the resist underlayer film. When the resist underlayer film contains a polymer containing a sulfonic acid group, the solubility thereof in a basic solution as a developer is enhanced, so that the resist underlayer film can be removed together with the resist film in the step of developing the resist film. The resist underlayer film may be developed only partially in the thickness direction from the outermost surface of the resist underlayer film, but is more preferably developed entirely in the thickness direction (that is, the entire resist underlayer film is removed in the exposed portion). The part of the resist underlayer film to be developed may be a part of the resist underlayer film in the planar direction. By developing the resist film with a basic solution and subsequently developing the resist underlayer film, an etching step of the resist underlayer film, which is conventionally necessary, can be omitted, and a good resist pattern can be efficiently formed through the reduction of the number of steps and the inhibition of the influence on other films and the like.

The basic solution for the alkali development is not particularly limited, and a publicly known basic solution can be used. Examples of the basic solution for the alkali development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1,5-diazabicyclo-[4.3.0]-5-nonene. Among them, the aqueous TMAH solution is preferable, and a 2.38% by mass aqueous TMAH solution is more preferable.

Examples of a developer in the case of performing organic solvent development include the same as those disclosed as the examples of the solvent [C] described above.

In this step, washing and/or drying may be performed after the development.

### [Etching Step]

In this step, etching is performed using the resist pattern (and the resist underlayer film pattern) as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₃, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

### <<Composition for Forming a Resist Underlayer Film>>

The composition for forming a resist underlayer film contains the polymer [A] and the solvent [C]. As such a composition for forming a resist underlayer film, the composition for forming a resist underlayer film to be used in the above-described method for manufacturing a semiconductor substrate can be suitably employed.

### EXAMPLES

Hereinbelow, the present invention will specifically be described on the basis of examples, but is not limited to these examples.

### [Weight-Average Molecular Weight (Mw)]

The Mw of a polymer (x-1) was measured by gel permeation chromatography (detector: differential refractometer) with monodisperse polystyrene standards using GPC columns (“G2000HXL”×2 and “G3000HXL”×1) manufactured by Tosoh Corporation under the following analysis conditions: flow rate: 1.0 mL/min; elution solvent: tetrahydrofuran; column temperature: 40° C.

[Average thickness of film]

The average thickness of a film was determined as a value obtained by measuring the film thickness at arbitrary nine points at intervals of 5 cm including the center of the resist underlayer film formed on a silicon wafer, using a spectroscopic ellipsometer (“M2000D” available from J. A. WOOLLAM Co.) and calculating the average value of the film thicknesses.

### <Synthesis of Monomer>

The following compounds a-1 to a-23 were used for synthesis of the polymer [A].

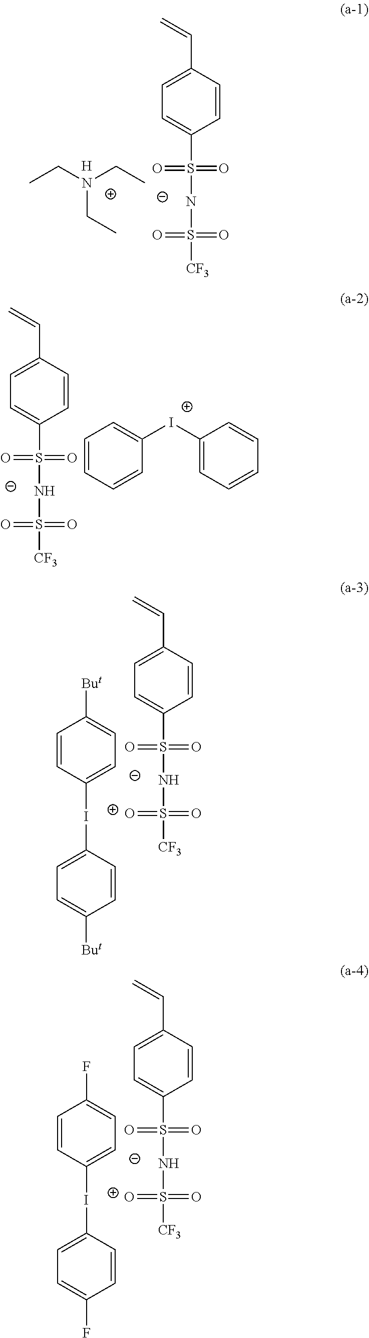

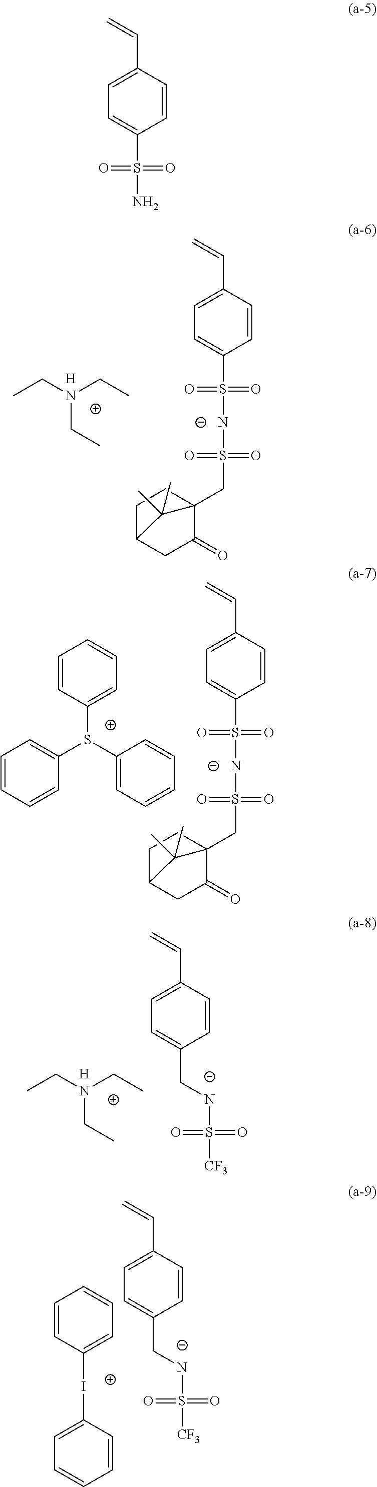

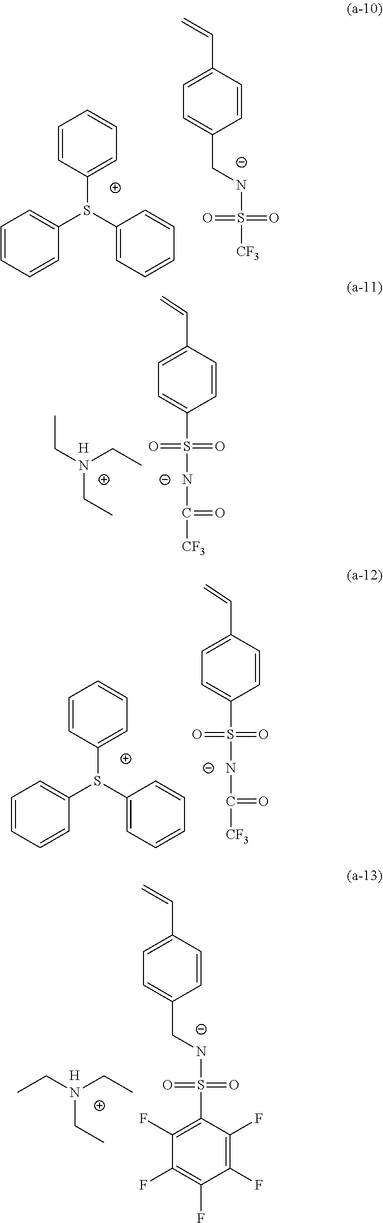

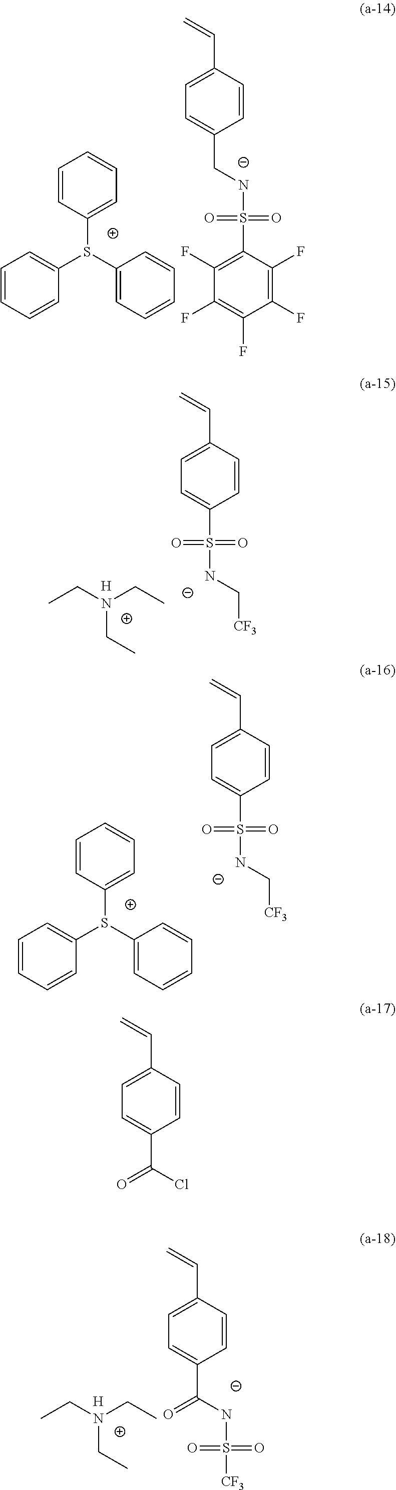

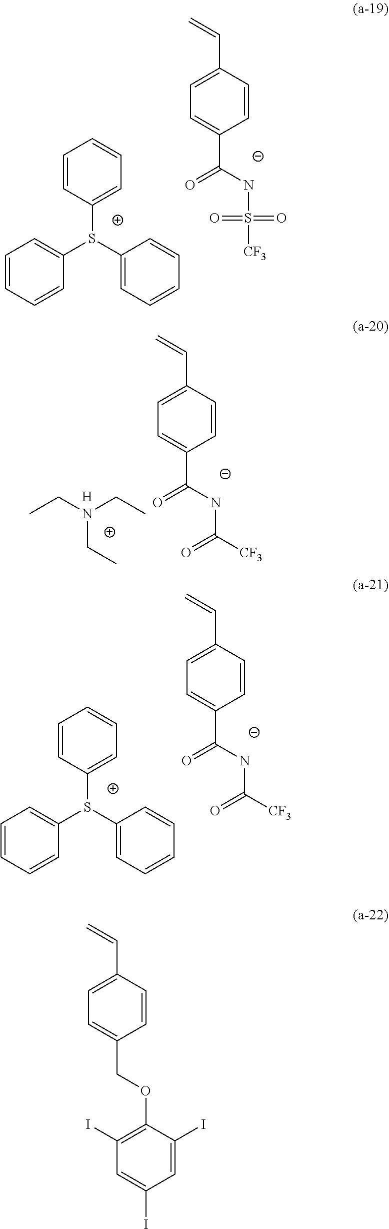

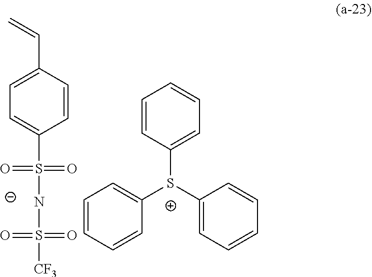

[Synthesis of a-1]

A 3 L three-necked flask equipped with a Dimroth condenser, a dropping funnel, and a stirrer bar was charged with 166 mL of dimethylformamide, 50 g of sodium styrenesulfonate, and 0.5 g of di-tert-butylcatechol, and then 87 mL of thionyl chloride was slowly dropped from the dropping funnel under salt-ice cooling, and the resulting mixture was stirred for 3 hours. After the stirring, about 200 g of cold water was added little by little, the generated hydrogen chloride was neutralized based on a trapping apparatus containing a 2 N aqueous NaOH solution, and excess thionyl chloride was decomposed. Thereafter, 200 g of diisopropyl ether was added, and extraction was performed three times. The diisopropyl ether layer was dried over sodium sulfate, and the sodium sulfate was removed by filtration with a pleated filter paper. The diisopropyl ether solution was concentrated under reduced pressure, and then the yield was determined by weighing and found to be 40.2 g. Next, a 2 L three-necked flask equipped with a Dimroth condenser, a dropping funnel, and a stirrer bar was charged with 29.8 g of trifluoromethanesulfonamide, 150 mL of methylene chloride, and 40.4 g of triethylamine, and then a mixed liquid of 40.8 g of styrenesulfonic acid chloride and 16 mL of methylene chloride was slowly dropped from the dropping funnel under ice cooling, and the resulting mixture was stirred for 6 hours. To the reaction solution was added 200 mL of ultrapure water, and washing with water was repeated three times. The organic layer was collected and water was removed with anhydrous sodium sulfate. Then, the filtrate was collected through a pleated filter paper, and methylene chloride was distilled off with an evaporator. The structure of the resulting target product was identified by ¹H-NMR spectrum and 80.2 g of the target product was obtained (yield: 96.3%).

1H-NMR (CDCl₃); 7.68 (m, 2H, Ph), 7.59 (m, 2H, Ph), 6.76 (q, 1H, CH), 5.76 (d, 1H, CH₂), 5.25 (d, 1H, CH₂), 3.28 (m, 6H, CH₂), 1.56 (t, 9H, CH₃).

[Synthesis of a-2]

In a 300 mL recovery flask, 10.5 g of the synthesized a-1 was dissolved in 100 mL of methylene chloride and 100 mL of ultrapure water, 9.1 g of diphenyliodonium chloride was added thereto, and the resulting mixture was stirred at room temperature for 8 hours. After completion of the reaction, water washing was performed three times with ultrapure water, and triethylamine hydrochloride generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by ¹H-, ¹³C-, and ¹⁹F-NMR spectra and 10.5 g of the target product was obtained (yield: 73.5%).

1H-NMR (DMSO-d₆); 8.27 (m, 4H, Ph), 7.83 (m, 2H, Ph), 7.75 (m, 2H, Ph), 7.67 (m, 4H, Ph), 7.59 (m, 2H, Ph), 6.72 (q, 1H, CH), 5.76 (d, 1H, CH₂), 5.25 (d, 1H, CH₂).

¹³C-NMR (DMSO-d₆); 155.7 (Ph), 140.1 (Ph), 136.2 (Ph), 135.4 (Ph), 129.4 (Ph), 127.0 (Ph), 126.5 (Ph), 117.1 (Ph), 113.4 (CF₃), 35.4 (CH), 31.2 (CH₂).

¹⁹F-NMR (DMSO-d₆); −77.4 (CF₃)

### Synthesis of a-3

In a 300 mL recovery flask, 10.5 g of a-1 was dissolved in 100 mL of methylene chloride and 100 mL of ultrapure water, 12.5 g of bis(4-t-butylphenyl) iodonium chloride was added thereto, and the resulting mixture was stirred at room temperature for 8 hours. After completion of the reaction, water washing was performed three times with ultrapure water, and triethylamine hydrochloride generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-, ¹³C-, and ¹⁹F-NMR spectra and 10.5 g of the target product was obtained (yield: 48.3%).

¹H-NMR (DMSO-d₆); 8.14 (m, 4H, Ph), 7.56 (m, 2H, Ph), 7.54 (m, 6H, Ph), 6.79 (m, 1H, CH), 5.97 (d, 1H, CH₂), 5.40 (d, 1H, CH₂), 1.26 (s, 18H, CH₃)

¹³C-NMR (DMSO-d₆); 155.6 (Ph), 136.2 (Ph), 135.4 (Ph), 129.3 (Ph), 127 (Ph), 126.5 (Ph), 117.2 (Ph), 113.9 (CH), 35.4 (C), 31.3 (CH₃).

¹⁹F-NMR (DMSO-d₆); −77.5 (CF₃).

[Synthesis of a-4]

In a 300 mL recovery flask, 10.5 g of a-1 was dissolved in 100 mL of methylene chloride and 100 mL of ultrapure water, 12.5 g of bis(4-fluorophenyl)iodonium chloride was added thereto, and the resulting mixture was stirred at room temperature for 8 hours. After completion of the reaction, water washing was performed three times with ultrapure water, and triethylamine hydrochloride generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-, ¹³C-, and ¹⁹F-NMR spectra and 10.5 g of the target product was obtained (yield: 72.6%).

¹H-NMR (DMSO-d₆); 8.34 (m, 4H, Ph), 7.72 (m, 2H, Ph), 7.59 (m, 2H, Ph), 7.42 (m, 2H, Ph), 6.78 (q, 1H, CH), 5.93 (d, 1H, CH₂), 5.37 (d, 1H, CH₂).

¹³C-NMR (DMSO-d₆); 165.7 (Ph), 163.2 (Ph), 144.8 (Ph), 140.2 (Ph), 138.5 (Ph), 136.1 (Ph), 127.0 (Ph), 126.5 (Ph), 119.9 (Ph), 119.7 (Ph), 117.2 (CF₃), 111.8 (CH),

¹⁹F-NMR (DMSO-d₆); −77.5 (CF₃), −106.6 (F-Ph).

[Synthesis of a-6]

A 2 L three-necked flask equipped with a Dimroth condenser, a dropping funnel, and a stirrer bar was charged with 33 g of styrenesulfonamide, 150 mL of methylene chloride, and 36.5 g of triethylamine, and then a mixed liquid of 45.2 g of (−)-10-camphorsulfonyl chloride and 16 mL of methylene chloride was slowly dropped from the dropping funnel under ice cooling, and the resulting mixture was stirred for 6 hours. To the reaction solution was added 200 mL of ultrapure water, and washing with water was repeated three times. The organic layer was collected and water was removed with anhydrous sodium sulfate. Then, the filtrate was collected through a pleated filter paper, and methylene chloride was distilled off with an evaporator, affording 85.2 g of a white powder (yield: 90.0%).

[Synthesis of a-7]

In a 300 mL recovery flask, 10.5 g of a-6 was dissolved in 100 mL of methylene chloride and 100 mL of ultrapure water, 7.4 g of triphenylsulfonium bromide was immediately added thereto, and the resulting mixture was stirred at room temperature for 8 hours. After completion of the reaction, water washing was performed three times with ultrapure water, and triethylamine hydrobromide generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-NMR spectrum and 12.5 g of a white powder was obtained (yield: 80.0%).

[Synthesis of a-8]

A 2 L three-necked flask equipped with a Dimroth condenser, a dropping funnel, and a stirrer bar was charged with 30 g of vinylbenzylamine, 150 mL of methylene chloride, and 45.6 g of triethylamine, and then a mixed liquid of 38.0 g of trifluoromethylsulfonic acid chloride and 16 mL of methylene chloride was slowly dropped from the dropping funnel under ice cooling, and the resulting mixture was stirred for 6 hours. To the reaction solution was added 200 mL of ultrapure water, and washing with water was repeated three times. The organic layer was collected and water was removed with anhydrous sodium sulfate. Then, the filtrate was collected through a pleated filter paper, and methylene chloride was distilled off with an evaporator. The structure of the resulting target product was identified by 1H-NMR spectrum and 70.2 g of a white powder was obtained (yield: 85.5%).

[Synthesis of a-9]

In a 300 mL recovery flask, 10.5 g of a-8 was dissolved in 100 mL of methylene chloride and 100 mL of ultrapure water, 9.1 g of diphenyliodonium chloride was immediately added thereto, and the resulting mixture was stirred at room temperature for 8 hours. After completion of the reaction, water washing was performed three times with ultrapure water, and triethylamine hydrochloride generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-NMR spectrum and 11.7 g of a white powder was obtained (yield: 75.0%).

[Synthesis of a-10]

In a 300 mL recovery flask, 10.5 g of a-8 was dissolved in 100 mL of methylene chloride and 100 mL of ultrapure water, 11.1 g of triphenylsulfonium bromide was immediately added thereto, and the resulting mixture was stirred at room temperature for 8 hours. After completion of the reaction, water washing was performed three times with ultrapure water, and triethylamine hydrobromide generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-NMR spectrum and 11.3 g of a white powder was obtained (yield: 75.0%).

[Synthesis of a-11]

A 2 L three-necked flask equipped with a Dimroth condenser, a dropping funnel, and a stirrer bar was charged with 30 g of a-5, 150 mL of methylene chloride, and 33.1 g of triethylamine, and then a mixed liquid of 12.5 g of trifluoroacetic acid chloride and 16 mL of methylene chloride was slowly dropped from the dropping funnel under ice cooling, and the resulting mixture was stirred for 6 hours. To the reaction solution was added 200 mL of ultrapure water, and washing with water was repeated three times. The organic layer was collected and water was removed with anhydrous sodium sulfate. Then, the filtrate was collected through a pleated filter paper, and methylene chloride was distilled off with an evaporator. The structure of the resulting target product was identified by 1H-NMR spectrum and 45.3 g of a white powder was obtained (yield: 85.0%).

[Synthesis of a-12]

In a 300 mL recovery flask, 10.5 g of a-11 was dissolved in 100 mL of methylene chloride and 100 mL of ultrapure water, 11.1 g of triphenylsulfonium bromide was immediately added thereto, and the resulting mixture was stirred at room temperature for 8 hours. After completion of the reaction, water washing was performed three times with ultrapure water, and triethylamine hydrobromide generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by ¹H-NMR spectrum and 11.3 g of a white powder was obtained (yield: 75.0%).

[Synthesis of a-13]

A 2 L three-necked flask equipped with a Dimroth condenser, a dropping funnel, and a stirrer bar was charged with 30 g of vinylbenzylamine, 150 mL of methylene chloride, and 45.6 g of triethylamine, and then a mixed liquid of 68.0 g of pentafluorobenzenesulfonic acid chloride and 50 mL of methylene chloride was slowly dropped from the dropping funnel under ice cooling, and the resulting mixture was stirred for 6 hours. To the reaction solution was added 200 mL of ultrapure water, and washing with water was repeated three times. The organic layer was collected and water was removed with anhydrous sodium sulfate. Then, the filtrate was collected through a pleated filter paper, and methylene chloride was distilled off with an evaporator. The structure of the resulting target product was identified by ¹H-NMR spectrum and 73.1 g of a white powder was obtained (yield: 70.5%).

[Synthesis of a-14]

In a 300 mL recovery flask, 10.5 g of a-13 was dissolved in 100 mL of methylene chloride and 100 mL of ultrapure water, 11.1 g of triphenylsulfonium bromide was immediately added thereto, and the resulting mixture was stirred at room temperature for 8 hours. After completion of the reaction, water washing was performed three times with ultrapure water, and triethylamine hydrobromide generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-NMR spectrum and 11.3 g of a white powder was obtained (yield: 75.0%).

[Synthesis of a-15]

A 2 L three-necked flask equipped with a Dimroth condenser, a dropping funnel, and a stirrer bar was charged with 14.7 g of trifluoroethylamine, 150 mL of methylene chloride, and 30.0 g of triethylamine, and then a mixed liquid of 30.0 g of styrenesulfonic acid chloride and 16 mL of methylene chloride was slowly dropped from the dropping funnel under ice cooling, and the resulting mixture was stirred for 6 hours. To the reaction solution was added 200 mL of ultrapure water, and washing with water was repeated three times. The organic layer was collected and water was removed with anhydrous sodium sulfate. Then, the filtrate was collected through a pleated filter paper, and methylene chloride was distilled off with an evaporator. The structure of the resulting target product was identified by 1H-NMR spectrum and 43.2 g of a white powder was obtained (yield: 80.0%).

[Synthesis of a-16]

In a 300 mL recovery flask, 10.5 g of a-15 was dissolved in 100 mL of methylene chloride and 100 mL of ultrapure water, 9.9 g of triphenylsulfonium bromide was immediately added thereto, and the resulting mixture was stirred at room temperature for 8 hours. After completion of the reaction, water washing was performed three times with ultrapure water, and triethylamine hydrobromide generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by ¹H-NMR spectrum and 12.1 g of a white powder was obtained (yield: 80.0%).

[Synthesis of a-18]

A 2 L three-necked flask equipped with a Dimroth condenser, a dropping funnel, and a stirrer bar was charged with 4.47 g of trifluorosulfonamide, 15 mL of methylene chloride, and 6.07 g of triethylamine, and then a mixed liquid of 5.00 g of a-17 and 5 mL of methylene chloride was slowly dropped from the dropping funnel under ice cooling, and the resulting mixture was stirred for 6 hours. To the reaction solution was added 50 mL of ultrapure water, and washing with water was repeated three times. The organic layer was collected and water was removed with anhydrous sodium sulfate. Then, the filtrate was collected through a pleated filter paper, and methylene chloride was distilled off with an evaporator. The structure of the resulting target product was identified by ¹H-NMR spectrum and 7.12 g of a white powder was obtained (yield: 85.0%).

[Synthesis of a-19]

In a 300 mL recovery flask, 10.0 g of a-18 was dissolved in 100 mL of methylene chloride and 100 mL of ultrapure water, 9.02 g of triphenylsulfonium bromide was immediately added thereto, and the resulting mixture was stirred at room temperature for 8 hours. After completion of the reaction, water washing was performed three times with ultrapure water, and triethylamine hydrobromide generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-NMR spectrum and 11.4 g of the target product was obtained (yield: 80.0%).

[Synthesis of a-20]

To a reaction vessel were added 6.79 g of trifluoroacetamide, 12.1 g of triethylamine, and 50 mL of methylene chloride, and then 10.0 g of a-17 and 10 mL of methylene chloride were added dropwise under ice cooling. The mixture was stirred at room temperature for 6 hours, 50 mL of ultrapure water was added to the reaction solution, and washing with water was repeated three times. The organic layer was collected and water was removed with anhydrous sodium sulfate. Then, the filtrate was collected through a pleated filter paper, and methylene chloride was distilled off with an evaporator. The structure of the resulting target product was identified by ¹H-NMR spectrum and 15.5 g of a white powder was obtained (yield: 75.0%).

[Synthesis of a-21]

In a 300 mL recovery flask, 10.0 g of a-20 was dissolved in 100 mL of methylene chloride and 100 mL of ultrapure water, 9.02 g of triphenylsulfonium bromide was immediately added thereto, and the resulting mixture was stirred at room temperature for 8 hours. After completion of the reaction, water washing was performed three times with ultrapure water, and triethylamine hydrobromide generated via the salt exchange reaction was removed. The organic layer was collected, concentrated with an evaporator, purified by column chromatography at methylene chloride/methanol=20/1 vol %, and concentrated with an evaporator, affording a light yellow solid. The structure of the target product was identified by 1H-NMR spectrum and 11.7 g of the target product was obtained (yield: 80.0%).

[Synthesis of a-22]

To a reaction vessel were added 10.0 g of chloromethylstyrene, 30.9 g of triiodophenol, 6.6 g of triethylamine, and 300 mL of methylene chloride, and the mixture was stirred at room temperature for 4 hours. After completion of the reaction, washing was performed once with a 5% aqueous oxalic acid solution and three times with ultrapure water. The organic layer was concentrated, purified by column chromatography at methylene chloride/methanol=20/1 vol %, and concentrated with an evaporator, affording a light yellow solid. The structure of the target product was identified by ¹H-NMR spectrum and 31 g of the target product was obtained (yield: 80.0%).

### <Synthesis of Polymer [A]>

The polymer [A] was synthesized by the following procedure. In the formulas shown in the Synthesis Examples disclosed below, the number attached to each repeating unit represents the content ratio (mol %) of the repeating unit. When no number is attached to a repeating unit, the content ratio of the repeating unit is 100 mol %. The same applies to the structural formula of the polymer [B]. The composition ratio was confirmed by ¹³C-NMR.

### [Synthesis Example 1-1] (Synthesis of Polymer (A-1))

Into a three-necked flask equipped with a thermometer, a Dimroth condenser, and a stirrer bar was charged 8 g of acetonitrile, which was then kept at 80° C. A mixed liquid of 4.0 g of a-2, 0.31 g of dimethyl 2,2-azobis(2-methylpropionate), and 4 g of acetonitrile was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of diisopropyl ether, affording 3.6 g of a white solid (yield: 90%). The obtained polymer (A-1) represented by the following formula (A-1) had an Mw of 16092, an Mn of 10088, and a molecular weight dispersion of 1.60.

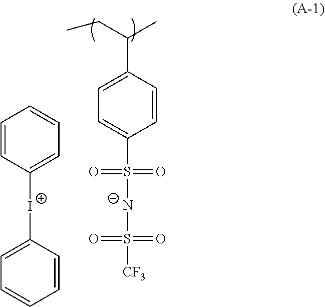

### [Synthesis Example 1-2] (Synthesis of Polymer (A-2))

Into a three-necked flask equipped with a thermometer, a Dimroth condenser, and a stirrer bar was charged 14 g of acetonitrile, which was then kept at 80° C. A mixed liquid of 7.0 g of a-3, 0.68 g of dimethyl 2,2-azobis(2-methylpropionate), and 7 g of acetonitrile was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of diisopropyl ether, affording 6.40 g of a white solid (yield: 91.4%). The obtained polymer (A-2) represented by the following formula (A-2) had an Mw of 16190, an Mn of 10014, and a molecular weight dispersion of 1.62.

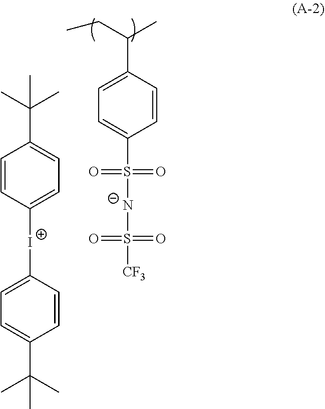

### [Synthesis Example 1-3] (Synthesis of Polymer (A-3))

Into a three-necked flask equipped with a thermometer, a Dimroth condenser, and a stirrer bar was charged 14 g of diacetonitrile, which was then kept at 80° C. A mixed liquid of 7.0 g of a-4, 0.77 g of dimethyl 2,2-azobis(2-methylpropionate), and 7 g of acetonitrile was added dropwise from a feeder over 3 hours. After completion of the dropwise addition, the mixture was aged at 80° C. for 3 hours. The resulting polymerization liquid was precipitated and purified with a 10 times amount of methanol, affording 8 g of a white solid (yield: 95%). The obtained polymer (A-3) represented by the following formula (A-3) had an Mw of 16332, an Mn of 10112, and a molecular weight dispersion of 1.62.

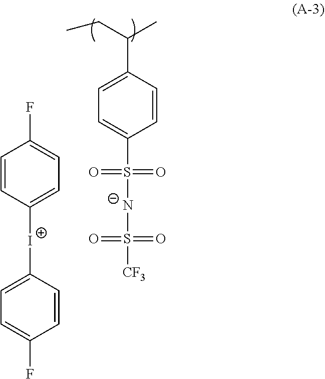

### [Synthesis Example 1-4] (Synthesis of Polymer (A-4))

Into a three-necked flask equipped with a thermometer, a Dimroth condenser, and a stirrer bar was charged 8 g of acetonitrile, which was then kept at 80° C. A mixed liquid of 3.6 g of a-2, 0.42 g of styrene, 0.46 g of dimethyl 2,2-azobis(2-methylpropionate), and 4 g of acetonitrile was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of diisopropyl ether, affording 1.8 g of a white solid (yield: 45%). The obtained polymer (A-4) represented by the following formula (A-4) had an Mw of 10092, an Mn of 6288, and a molecular weight dispersion of 1.60.

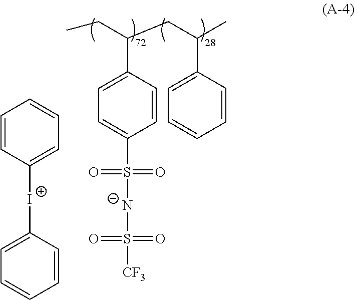

### [Synthesis Example 1-5](Synthesis of Polymer (A-5))

Into a three-necked flask equipped with a thermometer, a Dimroth condenser, and a stirrer bar was charged 8 g of acetonitrile, which was then kept at 80° C. A mixed liquid of 3.4 g of a-2, 0.66 g of 4-t-butoxystyrene, 0.43 g of dimethyl 2,2-azobis(2-methylpropionate), and 4 g of acetonitrile was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of diisopropyl ether, affording 2.8 g of a white solid (yield: 70%). The obtained polymer (A-5) represented by the following formula (A-5) had an Mw of 17340, an Mn of 10632, and a molecular weight dispersion of 1.63.

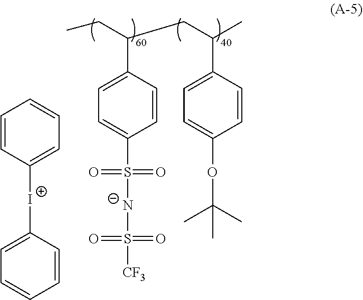

### [Synthesis Example 1-6](Synthesis of Polymer (A-6))

Into a three-necked flask equipped with a thermometer, a Dimroth condenser, and a stirrer bar was charged 8 g of acetonitrile, which was then kept at 80° C. A mixed liquid of 2.0 g of a-2, 2.1 g of t-butyl methacrylate, 0.79 g of dimethyl 2,2-azobis(2-methylpropionate), and 4 g of acetonitrile was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of diisopropyl ether, affording 2.9 g of a white solid (yield: 72%). The obtained polymer (A-6) represented by the following formula (A-6) had an Mw of 15600, an Mn of 9760, and a molecular weight dispersion of 1.60.

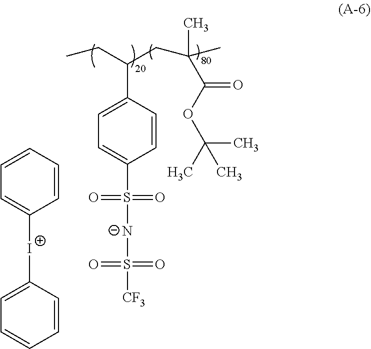

### [Synthesis Example 1-7](Synthesis of Polymer (A-7))

Into a three-necked flask equipped with a thermometer, a Dimroth condenser, and a stirrer bar was charged 8 g of acetonitrile, which was then kept at 80° C. A mixed liquid of 3.3 g of a-2, 0.70 g of 4-glycidyloxymethylstyrene, 0.43 g of dimethyl 2,2-azobis(2-methylpropionate), and 4 g of acetonitrile was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of diisopropyl ether, affording 3.2 g of a white solid (yield: 80%). The obtained polymer (A-7) represented by the following formula (A-7) had an Mw of 17320, an Mn of 10654, and a molecular weight dispersion of 1.63.

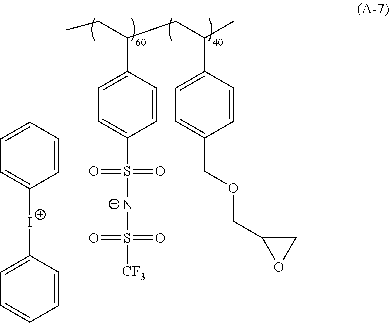

### [Synthesis Example 1-8](Synthesis of Polymer (A-8))

Into a three-necked flask equipped with a thermometer, a Dimroth condenser, and a stirrer bar was charged 8 g of N,N-dimethylacetamide, which was then kept at 80° C. A mixed liquid of 3.3 g of a-23, 3.23 g of 2-vinylnaphthalene, 1.81 g of 4-propargyloxystyrene, 1.75 g of dimethyl 2,2-azobis(2-methylpropionate), and 4 g of N,N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 6.67 g of a white solid (yield: 80%). The resulting polymer (A-8) had an Mw of 12200, an Mn of 6777, and a molecular weight dispersion of 1.8.

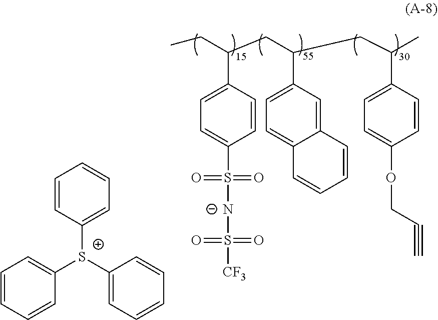

### [Synthesis Example 1-9](Synthesis of Polymer (A-9))

Into a three-necked flask equipped with a thermometer, a Dimroth condenser, and a stirrer bar was charged 8 g of N,N-dimethylacetamide, which was then kept at 80° C. A mixed liquid of 3.3 g of a-7, 2.83 g of 2-vinylnaphthalene, 1.81 g of 4-propargyloxystyrene, 1.85 g of dimethyl 2,2-azobis(2-methylpropionate), and 4 g of N,N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 7.62 g of a white solid (yield: 80%). The resulting polymer (A-9) had an Mw of 12200, an Mn of 6777, and a molecular weight dispersion of 1.8.

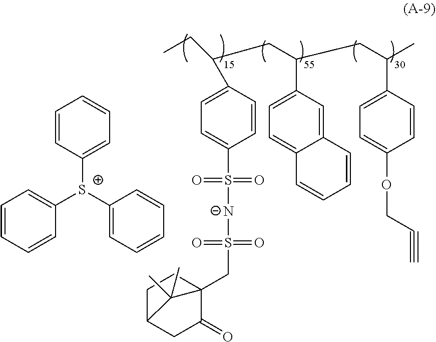

### [Synthesis Example 1-10](Synthesis of Polymer (A-10))

Into a three-necked flask equipped with a thermometer, a Dimroth condenser, and a stirrer bar was charged 8 g of N,N-dimethylacetamide, which was then kept at 80° C. A mixed liquid of 3.00 g of a-9, 0.21 g of dimethyl 2,2-azobis(2-methylpropionate), and 4 g of N,N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 2.57 g of a white solid (yield: 80%). The resulting polymer (A-10) had an Mw of 8400, an Mn of 4670, and a molecular weight dispersion of 1.8.

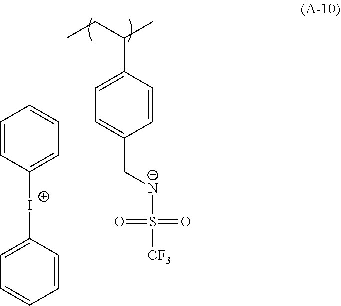

### [Synthesis Example 1-11](Synthesis of Polymer (A-11))

Into a three-necked flask equipped with a thermometer, a Dimroth condenser, and a stirrer bar was charged 8 g of N,N-dimethylacetamide, which was then kept at 80° C. A mixed liquid of 3.3 g of a-9, 4.67 g of N-vinylcarbazole, 5.93 g of 3,4-epoxycyclohexylmethyl methacrylate, 2.78 g of dimethyl 2,2-azobis(2-methylpropionate), and 4 g of N,N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 9.76 g of a white solid (yield: 80%). The resulting polymer (A-11) had an Mw of 9800, an Mn of 5440, and a molecular weight dispersion of 1.8.

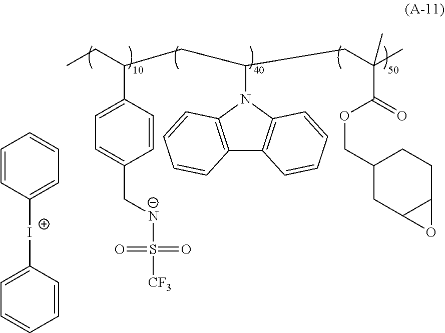

### [Synthesis Example 1-12](Synthesis of Polymer (A-12))

Into a three-necked flask equipped with a thermometer, a Dimroth condenser, and a stirrer bar was charged 8 g of N,N-dimethylacetamide, and a mixed liquid of 3.3 g of a-9, 4.67 g of N-vinylcarbazole, 4.05 g of vinylbenzyl alcohol, 2.78 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 11.84 g of a white solid (yield: 80%). The resulting polymer (A-12) had an Mw of 9800, an Mn of 5440, and a molecular weight dispersion of 1.8.

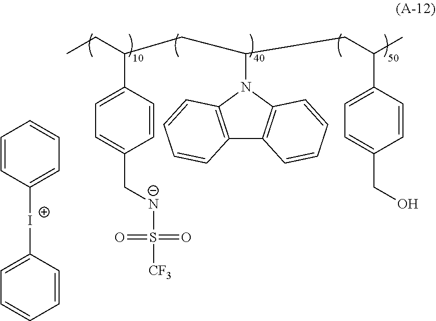

### [Synthesis Example 1-13](Synthesis of Polymer (A-13))

Into a three-necked flask equipped with a thermometer, a Dimroth condenser, and a stirrer bar was charged 8 g of N,N-dimethylacetamide, and a mixed liquid of 3.3 g of a-9, 4.68 g of N-vinylcarbazole, 4.79 g of 4-propargyloxystyrene, 2.79 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 11.05 g of a white solid (yield: 80%). The resulting polymer (A-13) had an Mw of 9800, an Mn of 5440, and a molecular weight dispersion of 1.8.

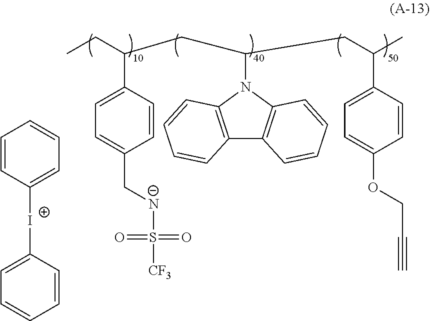

### [Synthesis Example 1-14](Synthesis of Polymer (A-14))

Into a three-necked flask equipped with a thermometer, a Dimroth condenser, and a stirrer bar was charged 8 g of N,N-dimethylacetamide, and a mixed liquid of 3.3 g of a-9, 3.68 g of acenaphthylene, 4.06 g of vinylbenzyl alcohol, 2.79 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 11.86 g of a white solid (yield: 80%). The resulting polymer (A-14) had an Mw of 9800, an Mn of 5440, and a molecular weight dispersion of 1.8.

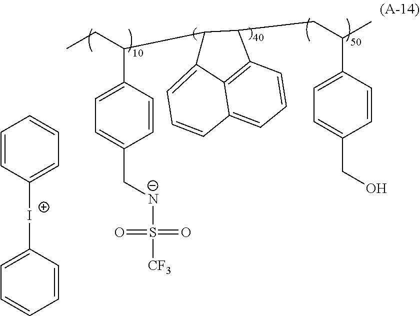

### [Synthesis Example 1-15](Synthesis of Polymer (A-15))

Into a three-necked flask equipped with a thermometer, a Dimroth condenser, and a stirrer bar was charged 8 g of N,N-dimethylacetamide, and a mixed liquid of 3.3 g of a-10, 4.83 g of N-vinylcarbazole, 4.95 g of 4-propargyloxystyrene, 2.88 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 12.77 g of a white solid (yield: 80%). The resulting polymer (A-15) had an Mw of 9800, an Mn of 5440, and a molecular weight dispersion of 1.8.

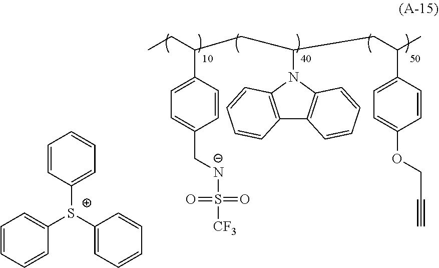

### [Synthesis Example 1-16](Synthesis of Polymer (A-16))

Into a three-necked flask equipped with a thermometer, a Dimroth condenser, and a stirrer bar was charged 8 g of N,N-dimethylacetamide, and a mixed liquid of 3.3 g of a-12, 4.83 g of vinylbenzylphthalimide, 1.98 g of 4-propargyloxystyrene, 1.92 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 10.59 g of a white solid (yield: 80%). The resulting polymer (A-16) had an Mw of 9800, an Mn of 5440, and a molecular weight dispersion of 1.8.

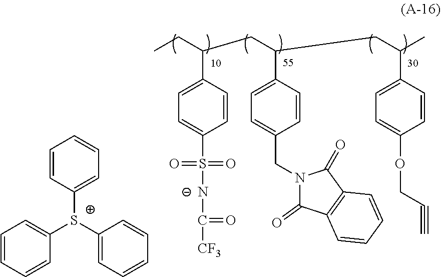

### [Synthesis Example 1-17](Synthesis of Polymer (A-17))

Into a three-necked flask equipped with a thermometer, a Dimroth condenser, and a stirrer bar was charged 8 g of N,N-dimethylacetamide, and a mixed liquid of 3.3 g of a-12, 3.45 g of vinylnaphthalene, 1.93 g of 4-propargyloxystyrene, 1.87 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 8.59 g of a white solid (yield: 80%). The resulting polymer (A-17) had an Mw of 9800, an Mn of 5440, and a molecular weight dispersion of 1.8.

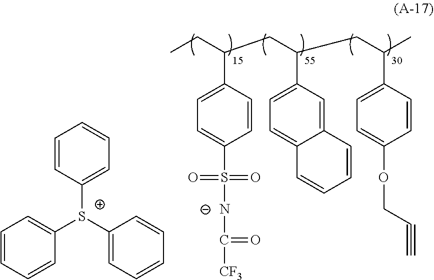

### [Synthesis Example 1-18](Synthesis of Polymer (A-18))

Into a three-necked flask equipped with a thermometer, a Dimroth condenser, and a stirrer bar was charged 8 g of N,N-dimethylacetamide, and a mixed liquid of 3.3 g of a-12, 2.19 g of α-methylene-γ-butyrolactone, 1.93 g of 4-propargyloxystyrene, 1.87 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 7.43 g of a white solid (yield: 80%). The resulting polymer (A-18) had an Mw of 9800, an Mn of 5440, and a molecular weight dispersion of 1.8.

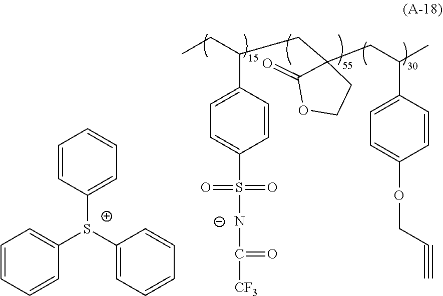

### [Synthesis Example 1-19](Synthesis of Polymer (A-19))

Into a three-necked flask equipped with a thermometer, a Dimroth condenser, and a stirrer bar was charged 8 g of N,N-dimethylacetamide, and a mixed liquid of 3.3 g of a-10, 3.80 g of vinylnaphthalene, 2.12 g of 4-propargyloxystyrene, 2.06 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 9.02 g of a white solid (yield: 80%). The resulting polymer (A-19) had an Mw of 9800, an Mn of 5440, and a molecular weight dispersion of 1.8.

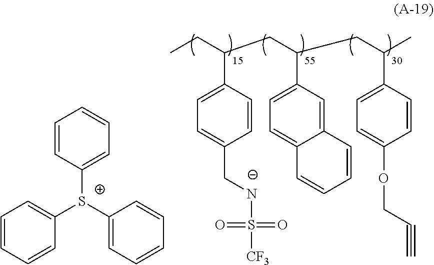

### [Synthesis Example 1-20](Synthesis of Polymer (A-20))

Into a three-necked flask equipped with a thermometer, a Dimroth condenser, and a stirrer bar was charged 8 g of N,N-dimethylacetamide, and a mixed liquid of 3.3 g of a-14, 4.08 g of N-vinylcarbazole, 4.17 g of 4-propargyloxystyrene, 2.43 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 11.18 g of a white solid (yield: 80%). The resulting polymer (A-20) had an Mw of 9800, an Mn of 5440, and a molecular weight dispersion of 1.8.

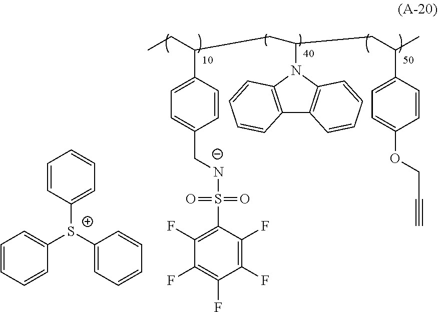

### [Synthesis Example 1-21](Synthesis of Polymer (A-21))

Into a three-necked flask equipped with a thermometer, a Dimroth condenser, and a stirrer bar was charged 8 g of N,N-dimethylacetamide, and a mixed liquid of 3.3 g of a-16, 4.83 g of N-vinylcarbazole, 4.95 g of 4-propargyloxystyrene, 2.88 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 12.77 g of a white solid (yield: 80%). The resulting polymer (A-21) had an Mw of 9800, an Mn of 5440, and a molecular weight dispersion of 1.8.

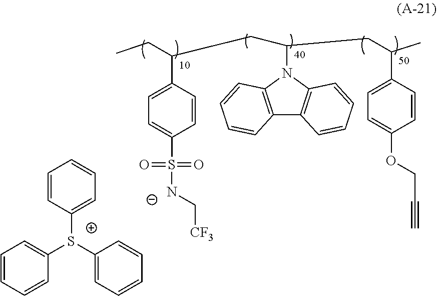

### [Synthesis Example 1-22](Synthesis of Polymer (A-22))

Into a three-necked flask equipped with a thermometer, a Dimroth condenser, and a stirrer bar was charged 8 g of N,N-dimethylacetamide, and a mixed liquid of 3.3 g of a-19, 4.71 g of N-vinylcarbazole, 4.82 g of 4-propargyloxystyrene, 2.81 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 12.51 g of a white solid (yield: 80%). The resulting polymer (A-22) had an Mw of 9800, an Mn of 5440, and a molecular weight dispersion of 1.8.

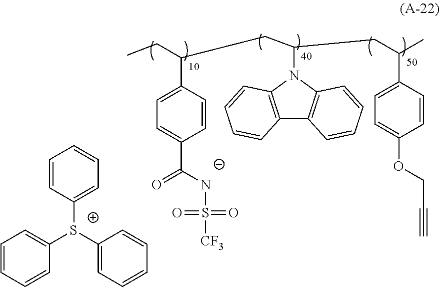

### [Synthesis Example 1-23](Synthesis of Polymer (A-23))

Into a three-necked flask equipped with a thermometer, a Dimroth condenser, and a stirrer bar was charged 8 g of N,N-dimethylacetamide, and a mixed liquid of 3.3 g of a-12, 4.71 g of N-vinylcarbazole, 4.82 g of 4-propargyloxystyrene, 2.81 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 12.51 g of a white solid (yield: 80%). The resulting polymer (A-23) had an Mw of 9800, an Mn of 5440, and a molecular weight dispersion of 1.8.

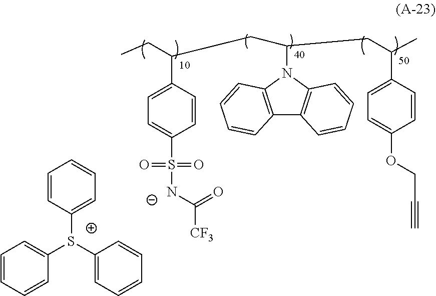

### [Synthesis Example 1-24](Synthesis of Polymer (A-24))

Into a three-necked flask equipped with a thermometer, a Dimroth condenser, and a stirrer bar was charged 8 g of N,N-dimethylacetamide, and a mixed liquid of 3.3 g of a-21, 5.05 g of N-vinylcarbazole, 5.16 g of 4-propargyloxystyrene, 3.01 g of dimethyl 2,2-azobis(2-methylpropionate), and 4 g of N,N-dimethylacetamide was added dropwise from a feeder at 80° C. over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 13.22 g of a white solid (yield: 80%). The resulting polymer (A-24) had an Mw of 9800, an Mn of 5440, and a molecular weight dispersion of 1.8.

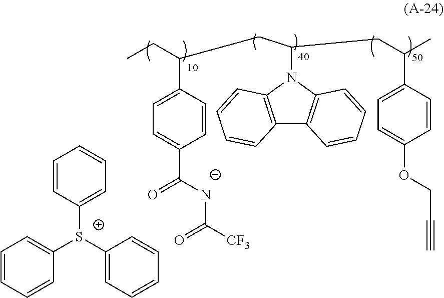

### [Synthesis Example 1-25](Synthesis of Polymer (A-25))

Into a three-necked flask equipped with a thermometer, a Dimroth condenser, and a stirrer bar was charged 8 g of N,N-dimethylacetamide, which was then kept at 80° C. A mixed liquid of 3.3 g of a-23, 6.60 g of 4-iodostyrene, 3.60 g of 4-propargyloxystyrene, 2.60 g of dimethyl 2,2-azobis(2-methylpropionate), and 4 g of N,N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 12.9 g of a white solid (yield: 80%). The resulting polymer (A-25) had an Mw of 12200, an Mn of 6777, and a molecular weight dispersion of 1.8.

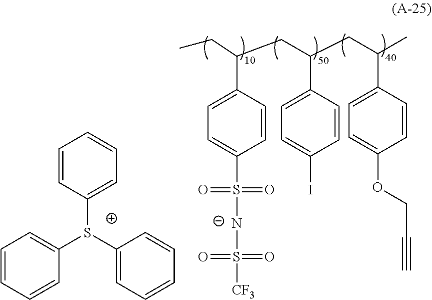

### [Synthesis Example 1-26](Synthesis of Polymer (A-26))

Into a three-necked flask equipped with a thermometer, a Dimroth condenser, and a stirrer bar was charged 8 g of N,N-dimethylacetamide, which was then kept at 80° C. A mixed liquid of 3.3 g of a-23, 17.0 g of triiodophenoxymethylstyrene, 3.60 g of 4-propargyloxystyrene, 2.60 g of dimethyl 2,2-azobis(2-methylpropionate), and 4 g of N,N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 12.9 g of a white solid (yield: 80%). The resulting polymer (A-26) had an Mw of 12200, an Mn of 6777, and a molecular weight dispersion of 1.8.

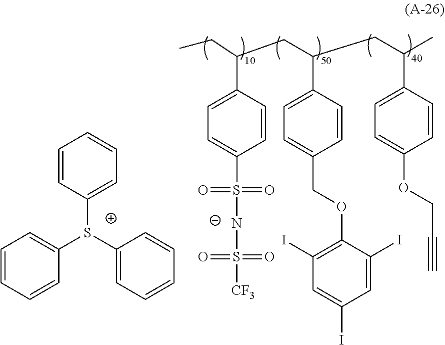

### <Synthesis of Polymer [B]>

The polymers represented by formulas (B-1) to (B-11) (hereinafter also referred to as “polymers (B-1)” and the like) were each synthesized by the following procedure.

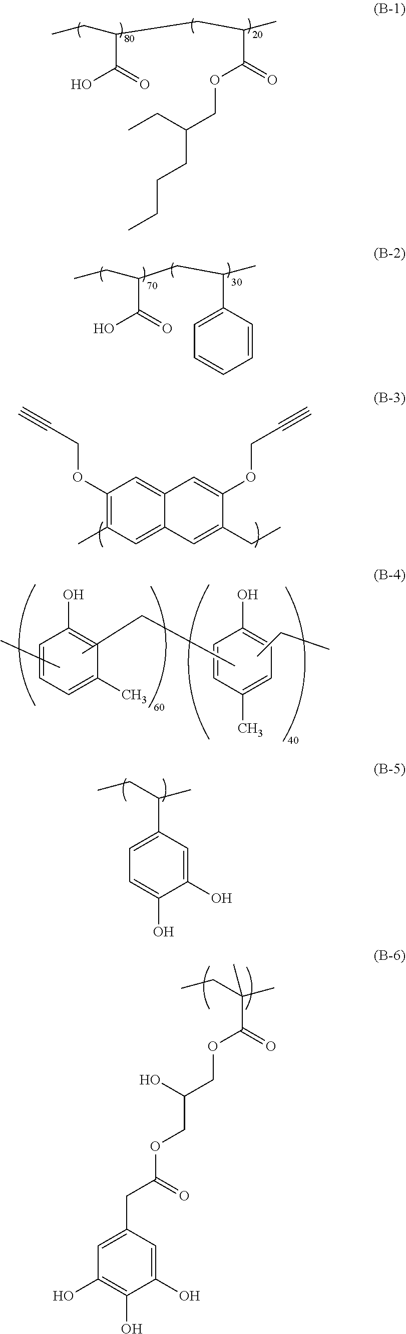

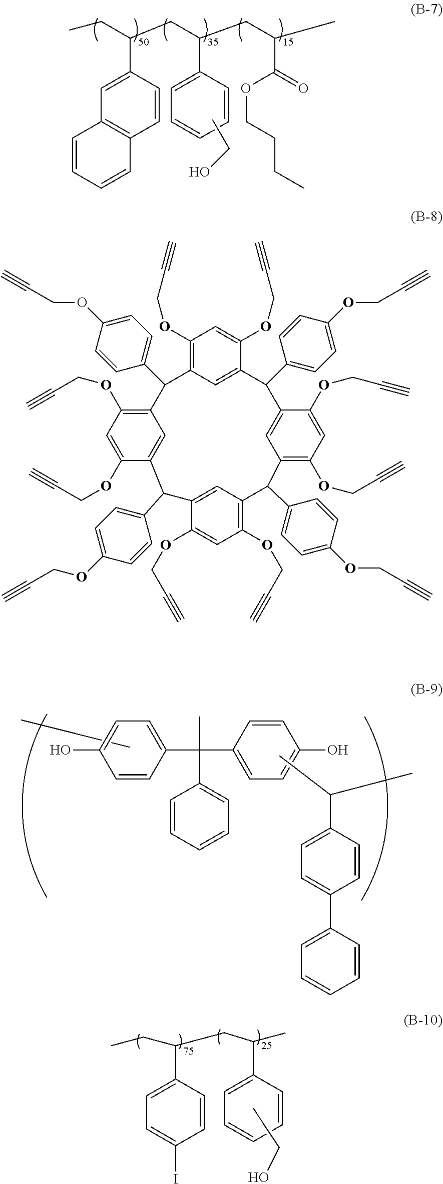

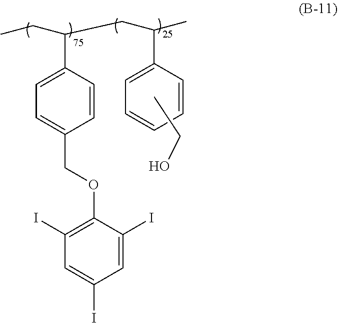

### [Synthesis Example 2-1](Synthesis of Polymer (B-1))

63 g of acrylic acid, 36 g of 2-ethylhexyl acrylate, and 21.2 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (B-1). The Mw of the polymer (B-1) was 6,500.

### [Synthesis Example 2-2](Synthesis of Polymer (B-2))

66 g of acrylic acid, 34 g of styrene, and 25.1 g of dimethyl 2,2′-azobis(2-methylpropionate) were added to prepare a monomer solution. In a nitrogen atmosphere, 300 g of methyl isobutyl ketone was placed in a reaction vessel and heated to 80° C., and the monomer solution was added dropwise over 3 hours with stirring. A polymerization reaction was performed for 6 hours with the start of the dropwise addition regarded as the start time of the polymerization reaction, and then the resulting mixture was cooled to 30° C. or lower. To the resulting reaction solution was added 300 g of propylene glycol monomethyl ether, and methyl isobutyl ketone was removed by concentration under reduced pressure, affording a propylene glycol monomethyl ether solution of polymer (B-2). The Mw of the polymer (B-2) was 5,300.

### [Synthesis Example 2-3] Synthesis of Polymer (B-3)

In a nitrogen atmosphere, 29.1 g of 2,7-dihydroxynaphthalene, 14.8 g of a 37% by mass formaldehyde solution, and 87.3 g of methyl isobutyl ketone were charged into a reaction and dissolved. After adding 1.0 g of p-toluenesulfonic acid monohydrate to the reaction vessel, and then the mixture was heated to 85° C. and reacted for 4 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (b-3) having a repeating unit represented by formula (b-3). The Mw of the polymer (b-3) was 3,400.

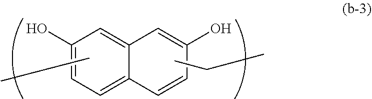

In a nitrogen atmosphere, 16.8 g of the polymer (b-3), 34.9 g of propargyl bromide, 90 g of methyl isobutyl ketone, and 45.0 g of methanol were added to a reaction vessel, and the mixture was stirred. Then, 106.9 g of a 25% by mass aqueous tetramethylammonium hydroxide solution was added thereto, and the mixture was reacted at 50° C. for 6 hours. The reaction solution was cooled to 30° C., and then 200.0 g of a 5% by mass aqueous oxalic acid solution was added. After removing the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-3). The Mw of the polymer (B-3) was 4,500.

### [Synthesis Example 2-4](Synthesis of Polymer (B-4))

In a nitrogen atmosphere, 10.0 g of 3-methylphenol, 6.67 g of 4-methylphenol, 25.0 g of a 37% by mass formaldehyde solution, and 116.3 g of methyl isobutyl ketone were charged into a reaction vessel and dissolved. After adding 1.33 g of p-toluenesulfonic acid monohydrate to the reaction vessel, and then the mixture was heated to 85° C. and reacted for 4 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-4). The Mw of the polymer (B-4) was 5,400.

### [Synthesis Example 2-5](Synthesis of Polymer (B-5))

In a nitrogen atmosphere, 10.0 g of catechol, 14.7 g of a 37% by mass formaldehyde solution, and 49.4 g of methyl isobutyl ketone were charged into a reaction vessel and dissolved. After adding 0.73 g of p-toluenesulfonic acid monohydrate to the reaction vessel, and then the mixture was heated to 85° C. and reacted for 4 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-5). The Mw of the polymer (B-5) was 3,400.

### [Synthesis Example 2-6](Synthesis of Polymer (B-6))

In a nitrogen atmosphere, 10.0 g of glycidyl methacrylate, 2.0 g of dimethyl 2,2-azobis(2-methylpropionate), and 20.4 g of methyl isobutyl ketone were charged into a reaction vessel and dissolved. The mixture was heated to 85° C. and reacted for 6 hours. After completion of the reaction, the reaction solution was transferred to a separatory funnel, 100 g of methyl isobutyl ketone and 200 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (b-6) represented by formula (b-6). The Mw of the polymer (b-6) was 7,200.

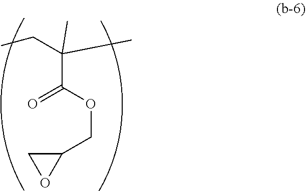

In a nitrogen atmosphere, 10.0 g of the polymer (b-6), 12.0 g of 3, 4, 5-trihydroxybenzoic acid hydrate, 90 g of methyl isobutyl ketone, and 45.0 g of methanol were added to a reaction vessel, and the mixture was stirred. Then, the mixture was reacted at 50° C. for 6 hours. The reaction solution was cooled to 30° C., and then 200.0 g of a 5% by mass aqueous oxalic acid solution was added. After removing the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-6). The Mw of the polymer (B-6) was 4,500.

### [Synthesis Example 2-7](Synthesis of Polymer (B-7))

In a nitrogen atmosphere, 10.0 g of 2-vinylnaphthalene, 6.09 g of vinylbenzyl alcohol, 2.49 g of butyl acetylate, and 5.97 g of dimethyl 2,2-azobis(2-methylpropionate) were charged into a reaction vessel, and the mixture was heated to 80° C. and reacted for 6 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-7). The Mw of the polymer (B-7) was 6,400.

### [Synthesis Example 2-8](Synthesis of Polymer (B-8))

In a nitrogen atmosphere, 10.0 g of 4-hydroxybenzaldehyde, 9.02 g of resorcinol, and 50 g of methanol were charged into a reaction vessel, and heated to 80° C. 1.00 g of p-toluenesulfonic acid was added thereto, and the mixture was reacted for 6 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (b-8) represented by formula (b-8). The Mw of the polymer (b-8) was 3,400.

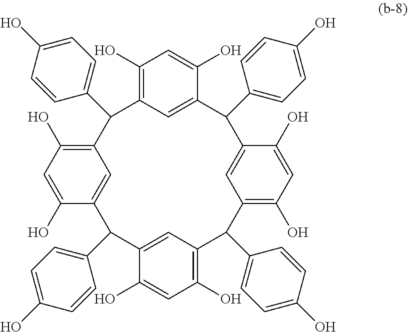 [SMILES: Oc1ccc(C2c3cc(c(O)cc3O)C(c3ccc(O)cc3)c3cc(c(O)cc3O)C(c3ccc(O)cc3)c3cc(c(O)cc3O)C(c3ccc(O)cc3)c3cc2c(O)cc3O)cc1]

In a nitrogen atmosphere, 18.0 g of the polymer (b-8), 39.0 g of propargyl bromide, 90 g of methyl isobutyl ketone, and 45.0 g of methanol were added to a reaction vessel, and the mixture was stirred. Then, 106.9 g of a 25% by mass aqueous tetramethylammonium hydroxide solution was added thereto, and the mixture was reacted at 50° C. for 6 hours. The reaction solution was cooled to 30° C., and then 200.0 g of a 5% by mass aqueous oxalic acid solution was added. After removing the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-8). The Mw of the polymer (B-8) was 4,500.

### [Synthesis Example 2-9](Synthesis of Polymer (B-9))

In a nitrogen atmosphere, 10.0 g of 4,4′-(1-phenylethylidene)diphenol, 6.28 g of biphenylaldehyde, and 49.4 g of methyl isobutyl ketone were charged into a reaction and dissolved. After adding 0.73 g of p-toluenesulfonic acid monohydrate to the reaction vessel, and then the mixture was heated to 85° C. and reacted for 4 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, affording polymer (B-9). The Mw of the polymer (B-9) was 6,200.

### [Synthesis Example 2-10](Synthesis of Polymer (B-10))

Into a three-necked flask equipped with a thermometer, a Dimroth condenser, and a stirrer bar was charged 8 g of N,N-dimethylacetamide, which was then kept at 80° C. A mixed liquid of 3.3 g of 4-iodostyrene, 0.64 g of vinylbenzyl alcohol, 0.88 g of dimethyl 2,2-azobis(2-methylpropionate), and 4 g of N, N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 3.15 g of a white solid (yield: 80%). The Mw of the polymer (B-10) was 12,200.

### [Synthesis Example 2-11](Synthesis of Polymer (B-11))

Into a three-necked flask equipped with a thermometer, a Dimroth condenser, and a stirrer bar was charged 8 g of N,N-dimethylacetamide, which was then kept at 80° C. A mixed liquid of 3.3 g of triiodophenoxymethylstyrene, 0.25 g of vinylbenzyl alcohol, 0.34 g of dimethyl 2,2-azobis(2-methylpropionate), and 4 g of N,N-dimethylacetamide was added dropwise from a feeder over 3 hours. After completion of the dropwise addition, the mixture was aged at 80° C. for 3 hours. The resulting polymerization liquid was concentrated with an evaporator, and then precipitated and purified with a 10 times amount of methyl isobutyl ketone, affording 2.84 g of a white solid (yield: 80%). The Mw of the polymer (B-11) was 8,200.

### <Preparation of Composition>

The polymer [A], the polymer [B], the solvent [C], and the crosslinking agent [D] used for the preparation of compositions are shown below.

### [Polymer [A]]

Polymers (A-1) to (A-26) synthesized above.

### [Polymer [B]]

Polymers (B-1) to (B-11) synthesized above.

### [Solvent [C]]

C-1: Propylene glycol monomethyl ether acetate

C-2: Propylene glycol monomethyl ether

C-3: 4-Methyl-2-pentanol

### [Crosslinking Agent [D]]

D-1: Compound represented by formula (D-1)

D-2: Compound represented by formula (D-2)

D-3: Compound represented by formula (D-3)

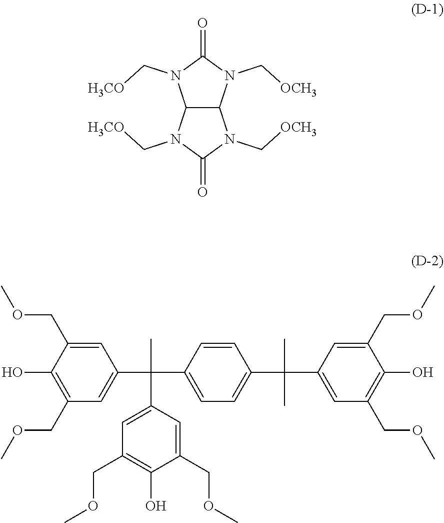

### Example 1

In 1100 parts by mass of (C-1) and 200 parts by mass of (C-2) as the solvent [C] were dissolved 50 parts by mass of (A-1) as the polymer [A] and 50 parts by mass of (D-2) as the crosslinking agent [D]. The resulting solution was filtered through a polytetrafluoroethylene (PTFE) membrane filter having a pore size of 0.45 μm to prepare a composition (J-1).

### Examples 2 to 57 and Comparative Examples 1 to 3

Compositions (J-2) to (J-57) and (CJ-1) to (CJ-3) were prepared in the same manner as in Example 1 except that the components of the types and contents shown in the following Table 1 were used. “-” in the columns [A], [B], and [D] in Table 1 each indicate that the corresponding component was not used.

TABLE 1

| | | | | | | | | Crosslinking | |
|---|---|---|---|---|---|---|---|---|---|
| | | Polymer [A] | | Polymer [B] | | Solvent [C] | | agent [D] | |
| | | | Content | | Content | | Content | | Content |
| | | | (parts by | | (parts by | | (parts by | | (parts by |
| | Composition | Type | mass) | Type | mass) | Type | mass) | Type | mass) |
| Example 1 | J-1 | A-1 | 50 | — | — | C-1/C-2 | 1100/200 | D-2 | 50 |
| Example 2 | J-2 | A-2 | 50 | — | — | C-1/C-2 | 1100/200 | D-2 | 50 |
| Example 3 | J-3 | A-3 | 50 | — | — | C-1/C-2 | 1100/200 | D-2 | 50 |
| Example 4 | J-4 | A-4 | 50 | — | — | C-1/C-2 | 1100/200 | D-2 | 50 |
| Example 5 | J-5 | A-5 | 100 | — | — | C-1/C-2 | 1100/200 | — | — |
| Example 6 | J-6 | A-7 | 100 | — | — | C-1/C-2 | 1100/200 | — | — |
| Example 7 | J-7 | A-5 | 50 | — | — | C-1/C-2 | 1100/200 | D-2 | 50 |
| Example 8 | J-8 | A-6 | 50 | — | — | C-1/C-2 | 1100/200 | D-2 | 50 |
| Example 9 | J-9 | A-7 | 50 | — | — | C-1/C-2 | 1100/200 | D-2 | 50 |
| Example 10 | J-10 | A-1 | 30 | B-1 | 20 | C-1/C-3 | 1100/200 | D-2 | 50 |
| Example 11 | J-11 | A-2 | 30 | B-2 | 20 | C-1/C-3 | 1100/200 | D-2 | 50 |
| Example 12 | J-12 | A-1 | 70 | — | — | C-1/C-2 | 1100/200 | D-2 | 30 |
| Example 13 | J-13 | A-1 | 30 | — | — | C-1/C-2 | 1100/200 | D-2 | 70 |
| Example 14 | J-14 | A-2 | 70 | — | — | C-1/C-2 | 1100/200 | D-2 | 30 |
| Example 15 | J-15 | A-2 | 30 | — | — | C-1/C-2 | 1100/200 | D-2 | 70 |
| Example 16 | J-16 | A-3 | 30 | — | — | C-1/C-2 | 1100/200 | D-2 | 30 |
| Example 17 | J-17 | A-3 | 70 | — | — | C-1/C-2 | 1100/200 | D-2 | 70 |
| Example 18 | J-18 | A-1 | 50 | — | — | C-1/C-2 | 1200/100 | D-2 | 50 |
| Example 19 | J-19 | A-1 | 50 | — | — | C-1/C-2 | 1250/50 | D-2 | 50 |
| Example 20 | J-20 | A-1 | 50 | — | — | C-1/C-2 | 1000/300 | D-2 | 50 |
| Example 21 | J-21 | A-1 | 50 | — | — | C-1/C-2 | 900/400 | D-2 | 50 |
| Example 22 | J-22 | A-1 | 50 | — | — | C-1/C-3 | 1100/200 | D-2 | 50 |
| Example 23 | J-23 | A-1 | 50 | — | — | C-1/C-2/C-3 | 1100/100/100 | D-2 | 50 |
| Example 24 | J-24 | A-1 | 50 | — | — | C-1/C-2 | 1100/200 | D-1 | 50 |
| Example 25 | J-25 | A-2 | 50 | — | — | C-1/C-2 | 1100/200 | D-1 | 50 |
| Example 26 | J-26 | A-3 | 50 | — | — | C-1/C-2 | 1100/200 | D-1 | 50 |
| Example 27 | J-27 | A-1 | 30 | B-3 | 20 | C-1/C-2 | 1100/200 | D-2 | 50 |
| Example 28 | J-28 | A-8 | 50 | — | — | C-1/C-4 | 200/1100 | D-2 | 50 |
| Example 29 | J-29 | A-8 | 50 | B-3 | 20 | C-1/C-4 | 200/1100 | D-2 | 30 |
| Example 30 | J-30 | A-8 | 50 | B-3 | 50 | C-1/C-4 | 200/1100 | — | — |
| Example 31 | J-31 | A-8 | 100 | — | — | C-1/C-4 | 200/1100 | — | — |
| Example 32 | J-32 | A-9 | 50 | B-3 | 50 | C-1/C-4 | 200/1100 | — | — |
| Example 33 | J-33 | A-10 | 50 | B-3 | 50 | C-1/C-4 | 200/1100 | — | — |
| Example 34 | J-34 | A-11 | 50 | B-3 | 50 | C-1/C-4 | 200/1100 | — | — |
| Example 35 | J-35 | A-12 | 50 | B-3 | 50 | C-1/C-4 | 200/1100 | — | — |
| Example 36 | J-36 | A-13 | 50 | B-3 | 50 | C-1/C-4 | 200/1100 | — | — |
| Example 37 | J-37 | A-14 | 50 | B-3 | 50 | C-1/C-4 | 200/1100 | — | — |
| Example 38 | J-38 | A-15 | 50 | B-3 | 50 | C-1/C-4 | 200/1100 | — | — |
| Example 39 | J-39 | A-16 | 50 | B-3 | 50 | C-1/C-4 | 200/1100 | — | — |
| Example 40 | J-40 | A-17 | 50 | B-3 | 50 | C-1/C-4 | 200/1100 | — | — |
| Example 41 | J-41 | A-18 | 50 | B-3 | 50 | C-1/C-4 | 200/1100 | — | — |
| Example 42 | J-42 | A-19 | 50 | B-3 | 50 | C-1/C-4 | 200/1100 | — | — |
| Example 43 | J-43 | A-20 | 50 | B-3 | 50 | C-1/C-4 | 200/1100 | — | — |
| Example 44 | J-44 | A-21 | 50 | B-3 | 50 | C-1/C-4 | 200/1100 | — | — |
| Example 45 | J-45 | A-22 | 50 | B-3 | 50 | C-1/C-4 | 200/1100 | — | — |
| Example 46 | J-46 | A-23 | 50 | B-3 | 50 | C-1/C-4 | 200/1100 | — | — |
| Example 47 | J-47 | A-24 | 50 | B-3 | 50 | C-1/C-4 | 200/1100 | — | — |
| Example 48 | J-48 | A-8 | 50 | B-4 | 50 | C-1/C-4 | 200/1100 | — | — |
| Example 49 | J-49 | A-8 | 50 | B-5 | 50 | C-1/C-4 | 200/1100 | — | — |
| Example 50 | J-50 | A-8 | 50 | B-6 | 50 | C-1/C-4 | 200/1100 | — | — |
| Example 51 | J-51 | A-8 | 50 | B-7 | 50 | C-1/C-4 | 200/1100 | — | — |
| Example 52 | J-52 | A-8 | 50 | B-8 | 50 | C-1/C-4 | 200/1100 | — | — |
| Example 53 | J-53 | A-8 | 50 | B-9 | 50 | C-1/C-4 | 200/1100 | — | — |
| Example 54 | J-54 | A-25 | 50 | B-3 | 50 | C-1/C-4 | 200/1100 | — | — |
| Example 55 | J-55 | A-25 | 50 | B-10 | 50 | C-1/C-4 | 200/1100 | — | — |
| Example 56 | J-56 | A-26 | 50 | B-3 | 50 | C-1/C-4 | 200/1100 | — | — |
| Example 57 | J-57 | A-26 | 50 | B-11 | 50 | C-1/C-4 | 200/1100 | — | — |
| Comparative | CJ-1 | — | — | B-1 | 100 | C-1/C-2 | 1100/200 | D-1 | 50 |
| Example 1 | | | | | | | | | |
| Comparative | CJ-2 | — | — | B-1 | 100 | C-1/C-2 | 1100/200 | D-1 | 50 |
| Example 2 | | | | | | | | | |
| Comparative | CJ-3 | — | — | B-2 | 100 | C-1/C-2 | 1100/200 | D-2 | 30 |
| Example 3 | | | | | | | | | |

### <Evaluation>

Using the compositions prepared as described above, the solvent resistance and the resist pattern rectangularity due to EUV exposure were evaluated by the following methods. The evaluation results are shown in Table 2.

### [Solvent Resistance]

A composition prepared above was applied to a 12-inch silicon wafer by spin coating using a spin coater (“CLEAN TRACK ACT 12” available from Tokyo Electron Limited). Next, the resultant was heated at 250° C. for 180 seconds in the air atmosphere, and then cooled at 23° C. for 60 seconds to form a resist underlayer film having an average thickness of 5 nm, thereby affording a substrate with a resist underlayer film, the substrate having a resist underlayer film formed thereon. The obtained substrate with a resist underlayer film was immersed in 2.38% tetramethylammonium hydroxide (23° C.) for 1 minute, and further immersed in ultrapure water for 1 minute. The average film thickness before and after the immersion was measured. Where the average thickness of the resist underlayer film before the immersion was X0 and the average thickness of the resist underlayer film after the immersion was X, the absolute value of the numerical value obtained by (X-X0)×100/X0 was calculated and taken as the film thickness change rate (%). The solvent resistance was evaluated as “A” (good) when the film thickness change rate was less than 1%, “B” (slightly good) when the film thickness change rate was 1% or more and less than 10%, and “C” (poor) when the film thickness change rate was 10% or more.

### <Preparation of Resist Composition>

A resist composition (R-1) was obtained by mixing 100 parts by mass of a polymer having a structural unit (1) derived from 4-hydroxystyrene, a structural unit (2) derived from styrene, and a structural unit (3) derived from 4-t-butoxystyrene (content ratio of each structural unit: (1)/(2)/(3)=65/5/30 (mol %)), 1.0 parts by mass of triphenylsulfonium trifluoromethanesulfonate as a radiation-sensitive acid generating agent, and 4,400 parts by mass of ethyl lactate and 1,900 parts by mass of propylene glycol monomethyl ether acetate each as a solvent, and filtering the obtained solution through a filter having a pore size of 0.2 μm.

### [Resist Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG080” manufactured by JSR Corporation), heated at 220° C. for 60 sec, and then cooled at 23° C. for 30 sec. Thus, a silicon-containing film having an average thickness of 20 nm was formed. The composition prepared as described above was applied to the silicon-containing film formed as described above to form a resist underlayer film. The resist underlayer film formed as described above was heated at 250° C. for 180 seconds, and then cooled at 23° C. for 30 seconds, affording a resist underlayer film having an average thickness of 5 nm. To the resist underlayer film formed as described above was applied a resist composition (R-1), heated at 130° C. for 60 sec, and then cooled at 23° C. for 30 sec. Thus, a resist film having an average thickness of 50 nm was formed. Next, the resist film was irradiated with extreme ultraviolet rays using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the irradiation with the extreme ultraviolet rays, the substrate was heated at 110° C. for 60 sec, followed by cooling at 23° C. for 60 sec. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“SU8220” available from Hitachi High-Technologies Corporation) was used for length measurement and observation of the resist pattern of the substrate for evaluation. The resist pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

TABLE 2

| | | Solvent | Resist pattern |
|---|---|---|---|
| | Composition | resistance | rectangularity |
| Example 1 | J-1 | A | A |
| Example 2 | J-2 | A | A |
| Example 3 | J-3 | A | A |
| Example 4 | J-4 | A | A |
| Example 5 | J-5 | A | A |
| Example 6 | J-6 | A | A |
| Example 7 | J-7 | A | A |
| Example 8 | J-8 | B | A |
| Example 9 | J-9 | B | A |
| Example 10 | J-10 | B | A |
| Example 11 | J-11 | A | A |
| Example 12 | J-12 | B | A |
| Example 13 | J-13 | A | A |
| Example 14 | J-14 | B | A |
| Example 15 | J-15 | A | A |
| Example 16 | J-16 | B | A |
| Example 17 | J-17 | A | A |
| Example 18 | J-18 | A | A |
| Example 19 | J-19 | A | A |
| Example 20 | J-20 | A | A |
| Example 21 | J-21 | A | A |
| Example 22 | J-22 | A | A |
| Example 23 | J-23 | A | A |
| Example 24 | J-24 | A | A |
| Example 25 | J-25 | A | A |
| Example 26 | J-26 | A | A |
| Example 27 | J-27 | A | A |
| Example 28 | J-28 | A | A |
| Example 29 | J-29 | A | A |
| Example 30 | J-30 | A | A |
| Example 31 | J-31 | A | A |
| Example 32 | J-32 | A | A |
| Example 33 | J-33 | A | A |
| Example 34 | J-34 | A | A |
| Example 35 | J-35 | A | A |
| Example 36 | J-36 | A | A |
| Example 37 | J-37 | A | A |
| Example 38 | J-38 | A | A |
| Example 39 | J-39 | A | A |
| Example 40 | J-40 | A | A |
| Example 41 | J-41 | A | A |
| Example 42 | J-42 | A | A |
| Example 43 | J-43 | A | A |
| Example 44 | J-44 | A | A |
| Example 45 | J-45 | A | A |
| Example 46 | J-46 | A | A |
| Example 47 | J-47 | A | A |
| Example 48 | J-48 | A | A |
| Example 49 | J-49 | A | A |
| Example 50 | J-50 | A | A |
| Example 51 | J-51 | A | A |
| Example 52 | J-52 | A | A |
| Example 53 | J-53 | A | A |
| Example 54 | J-54 | A | A |
| Example 55 | J-55 | A | A |
| Example 56 | J-56 | A | A |
| Example 57 | J-57 | A | A |
| Comparative | CJ-1 | C | B |
| Example 1 | | | |
| Comparative | CJ-2 | C | B |
| Example 2 | | | |
| Comparative | CJ-3 | C | B |
| Example 3 | | | |

### <Evaluation>

Using the compositions prepared as described above, the resist pattern rectangularity due to KrF exposure was evaluated by the following method. The evaluation results are given in the following Table 3.

### [Resist Pattern Rectangularity (KrF Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG800” manufactured by JSR Corporation), heated at 220° C. for 60 seconds, and then cooled at 23° C. for 30 seconds. Thus, a silicon-containing film having an average thickness of 20 nm was formed. The composition prepared as described above was applied to the silicon-containing film formed as described above to form a resist underlayer film. The resist underlayer film formed as described above was heated at 250° C. for 180 seconds, and then cooled at 23° C. for 30 seconds, affording a resist underlayer film having an average thickness of 5 nm. To the resist underlayer film formed was applied a resist composition (R-1), heated at 130° C. for 60 seconds, and then cooled at 23° C. for 30 seconds. Thus, a resist film having an average thickness of 50 nm was formed. Next, the resist film was irradiated with KrF rays using an KrF scanner (“NSR-S210D”, available from Nikon Corporation (NA=0.82; Sigma=inner 0.75, outer 0.91; Dipole illumination, with a 1:1 line and space mask having a line width of 130 nm in terms of a dimension on wafer)). After the irradiation with KrF rays, the substrate was heated at 110° C. for 60 seconds, followed by cooling at 23° C. for 60 seconds. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“CG5000” available from Hitachi High-Technologies Corporation) was used for length measurement and observation of the resist pattern of the substrate for evaluation. The resist pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

TABLE 3

| | | Resist pattern |
|---|---|---|
| | Composition | rectangularity |
| Example 58 | J-1 | A |
| Example 59 | J-2 | A |
| Example 60 | J-3 | A |
| Example 61 | J-4 | A |
| Example 62 | J-5 | A |
| Example 63 | J-6 | A |

### <Evaluation>

Using the compositions prepared as described above, the resist pattern rectangularity due to EB exposure was evaluated by the following method. The evaluation results are shown in Table 4.

### [Pattern Rectangularity (EB Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied a composition for forming a silicon-containing film (“NFC SOG800” manufactured by JSR Corporation), heated at 220° C. for 60 seconds, and then cooled at 23° C. for 30 seconds. Thus, a silicon-containing film having an average thickness of 20 nm was formed. The composition prepared as described above was applied to the silicon-containing film formed as described above to form a resist underlayer film. The resist underlayer film formed as described above was heated at 250° C. for 180 seconds, and then cooled at 23° C. for 30 seconds, affording a resist underlayer film having an average thickness of 5 nm. To the resist underlayer film formed was applied a resist composition (R-1), heated at 130° C. for 60 seconds, and then cooled at 23° C. for 30 seconds. Thus, a resist film having an average thickness of 50 nm was formed. Next, the resist film was exposed using an EB scanner (electron beam lithography system (manufactured by ELIONIX Inc.; ELS-F150, current: 1 pA, voltage: 150 kV, pattern size: 200 nm). After the irradiation with an electron beam, the substrate was heated at 110° C. for 60 seconds, followed by cooling at 23° C. for 60 seconds. Thereafter, development was performed by a paddle method using a 2.38% by mass aqueous tetramethylammonium hydroxide solution (20° C. to 25° C.), followed by washing with water and drying, thereby affording a substrate for evaluation having a resist pattern formed thereon. A scanning electron microscope (“CG5000” available from Hitachi High-Technologies Corporation) was used for length measurement and observation of the resist pattern of the substrate for evaluation. The resist pattern rectangularity was evaluated as “A” (good) when the cross-sectional shape of the pattern was rectangular, “B” (slightly good) when trailing was present in the cross section of the pattern, and “C” (poor) when a residue (defect) was present in the pattern.

TABLE 4

| | | Resist pattern |
|---|---|---|
| | Composition | rectangularity |
| Example 64 | J-1 | A |
| Example 65 | J-2 | A |
| Example 66 | J-3 | A |
| Example 67 | J-4 | A |
| Example 68 | J-5 | A |
| Example 69 | J-6 | A |

### <Evaluation>

Using the compositions prepared as described above, the resist pattern rectangularity due to EUV exposure was evaluated by the following method. The evaluation results are shown in Table 5.

### <Preparation of Resist Composition for EUV Exposure (R-2)>

The compound (S-1) to be used for the preparation of a resist composition for EUV exposure (R-2) was synthesized by the following procedure. In a reaction vessel, 6.5 parts by mass of isopropyltin trichloride was added while stirring 150 mL of a 0.5 N aqueous sodium hydroxide solution, and a reaction was carried out for 2 hours. The precipitate formed was collected by filtration, washed twice with 50 parts by mass of water, and then dried, affording a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

2 parts by mass of the compound (S-1) synthesized above and 98 parts by mass of propylene glycol monoethyl ether were mixed, and the resulting mixture was subjected to removal of residual water with activated 4 A molecular sieve, and then filtered through a filter having a pore size of 0.2 μm. Thus, a resist composition for EUV exposure (R-2) was prepared.

### [Pattern Rectangularity (EUV Exposure)]

A material for forming an organic underlayer film (“HM8006”, available from JSR Corporation) was applied on a 12-inch silicon wafer by spin-coating using a spin-coater (“CLEAN TRACK ACT12”, available from Tokyo Electron Ltd.), and thereafter heating was conducted at 250° C. for 60 sec to form an organic underlayer film having an average thickness of 100 nm. To the organic underlayer film was applied the composition for forming a resist underlayer film prepared above, heated at 220° C. for 60 sec, and then cooled at 23° C. for 30 sec. Thus, a resist underlayer film having an average thickness of 5 nm was formed. To the resist underlayer film was applied the resist composition for EUV exposure (R-2) by the spin coating method using the spin coater described above, and after a lapse of a prescribed time, heated at 90° C. for 60 sec, and then cooled at 23° C. for 30 sec. Thus, a resist film having an average thickness of 35 nm was formed. The resist film was exposed to light using an EUV scanner (“TWINSCAN NXE:3300B”, available from ASML Co. (NA=0.3; Sigma=0.9; quadrupole illumination, with a 1:1 line and space mask having a line width of 16 nm in terms of a dimension on wafer)). After the exposure, the substrate was heated at 110° C. for 60 sec, and subsequently cooled at 23° C. for 60 sec. Thereafter, development was performed by a paddle method using 2-heptanone (20 to 25° C.), and then dried, affording a substrate for evaluation with a resist pattern formed thereon. A scanning electron microscope (“CG-6300” available from Hitachi High-Tech Corporation) was used for length measurement and observation of the resist pattern of the substrate for evaluation. The pattern rectangularity was evaluated as “A” (good) when the cross-sectional shape of the pattern was rectangular, and “B” (poor) when trailing was present in the cross section of the pattern.

TABLE 5

| | | Resist pattern |
|---|---|---|
| | Composition | rectangularity |
| Example 70 | J-48 | A |
| Example 71 | J-49 | A |
| Example 72 | J-50 | A |
| Example 73 | J-51 | A |
| Example 74 | J-52 | A |
| Example 75 | J-53 | A |
| Example 76 | J-54 | A |
| Example 77 | J-55 | A |
| Example 78 | J-56 | A |
| Example 79 | J-57 | A |

As can be seen from the results in Tables 2 to 5, the resist underlayer films formed from the compositions of Examples were superior in solvent resistance and pattern rectangularity to the resist underlayer films formed from the compositions of Comparative Examples.

By the method for manufacturing a semiconductor substrate of the present disclosure, it is possible to efficiently manufacture a semiconductor substrate because of using a composition for forming a resist underlayer film capable of forming a resist underlayer film superior in solvent resistance and pattern rectangularity. When the composition for forming a resist underlayer film of the present disclosure is used, a film superior in solvent resistance and pattern rectangularity can be formed. Therefore, they can suitably be used for, for example, producing semiconductor devices.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, comprising:
applying a composition for forming a resist underlayer film directly or indirectly to a substrate to form a resist underlayer film;
applying a composition for forming a resist film to the resist underlayer film to form a resist film;
exposing the resist film to radiation; and
developing the exposed resist film,
wherein the composition for forming a resist underlayer film comprises:
a polymer comprising a partial structure represented by formula (i); and
a solvent, 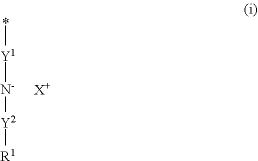
wherein, in the formula (i), Y¹ is a sulfonyl group, a carbonyl group, or an alkanediyl group; Y² is a sulfonyl group, a carbonyl group, or a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms; X⁺ is a monovalent onium cation; and * is a bond with another structure in the polymer.

2. The method according to claim 1, wherein
the polymer comprises a repeating unit represented by formula (1) 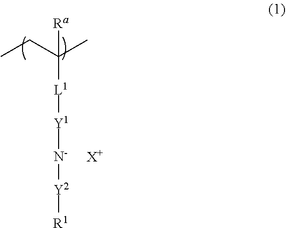
wherein, in the formula (1), R^{a} is a hydrogen atom or a substituted or unsubstituted monovalent hydrocarbon group having 1 to 20 carbon atoms; L¹ is a single bond or a divalent linking group other than an alkanediyl group; Y¹, Y², R¹, and X⁺ are each defined as in the formula (i).

3. The method according to claim 2, wherein L¹ is a divalent aromatic hydrocarbon group having 6 to 20 carbon atoms.

4. The method according to claim 1, further comprising, before applying the composition for forming a resist film, heating the resist underlayer film at 200° C. or higher.

5. The method according to claim 1, wherein the radiation is a KrF excimer laser, an electron beam, or an extreme ultraviolet ray.

6. The method for according to claim 1, wherein the resist underlayer film has a film thickness of 20 nm or less.

7. The method according to claim 1, wherein developing comprises developing the exposed resist film with a developer which is a basic solution.

8. The method according to claim 1, further comprising:
forming a silicon-containing film directly or indirectly on the substrate before applying the composition for forming a resist underlayer film.

9. A composition comprising:
a polymer comprising a partial structure represented by formula (i); and
a solvent, 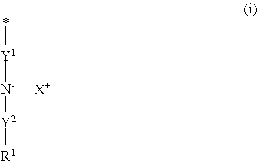
wherein, in the formula (i), Y¹ is a sulfonyl group, a carbonyl group, or an alkanediyl group; Y² is a sulfonyl group, a carbonyl group, or a single bond; when Y¹ is an alkanediyl group, Y² is a sulfonyl group or a carbonyl group, and when Y² is a single bond, Y¹ is a sulfonyl group or a carbonyl group; R¹ is a monovalent organic group having 1 to 20 carbon atoms; X⁺ is a monovalent onium cation; and * is a bond with another structure in the polymer.

10. The composition according to claim 9, wherein
the polymer comprises a repeating unit represented by formula (1): 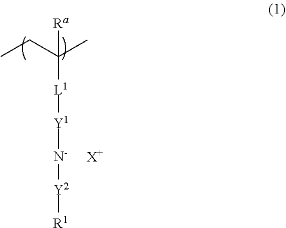
wherein, in the formula (1), R^{a} is a hydrogen atom or a substituted or unsubstituted monovalent hydrocarbon group having 1 to 20 carbon atoms; L¹ is a single bond or a divalent linking group other than an alkanediyl group; Y¹, Y², R¹, and X⁺ are each defined as in the formula (i).

11. The composition according to claim 10, wherein L¹ is a divalent aromatic hydrocarbon group having 6 to 20 carbon atoms.

12. The composition according to claim 9, wherein R¹ is a monovalent organic group having 1 to 20 carbon atoms in which a fluorine atom or a fluorinated hydrocarbon group is bonded to a carbon atom adjacent to Y².

13. The composition according to claim 9, wherein
the polymer comprises a repeating unit represented by formula (2): 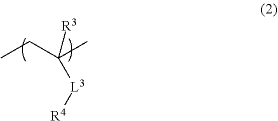
wherein, in the formula (2), R³ is a hydrogen atom or a substituted or unsubstituted monovalent hydrocarbon group having 1 to 20 carbon atoms; L³ is a single bond or a divalent linking group; and R⁴ is a monovalent organic group having 1 to 20 carbon atoms.

14. The composition according to claim 13, wherein L³ is a single bond, and R⁴ is a substituted or unsubstituted monovalent aromatic hydrocarbon group or a substituted or unsubstituted monovalent heterocyclic group.

15. The composition according to claim 10, wherein a content ratio of the repeating unit represented by the formula (1) accounting for in all repeating units constituting the polymer is 1 mol % or more and 100 mol % or less.

16. The composition according to claim 9, wherein a content ratio of the polymer accounting for in components other than the solvent in the composition 10% by mass or more.

17. The composition according to claim 9, further comprising a crosslinking agent.

18. The composition according to claim 17, wherein a content ratio of the crosslinking agent accounting for in components other than the solvent in the composition is 10% by mass or more.
